(19) United States
(12) Patent Application Publication
(10) Pub. No.: US 2024/0357908 A1
(43) Pub. Date: Oct. 24, 2024

(54) DISPLAY APPARATUS AND MANUFACTURING METHOD OF THE SAME

(71) Applicant: Samsung Display Co., Ltd., Yongin-si (KR)

(72) Inventors: GIHOON YANG, Yongin-si (KR); TAEMIN KIM, Yongin-si (KR); JIYUN PARK, Yongin-si (KR); DONGGEUN SHIN, Yongin-si (KR); SEULGEE LEE, Yongin-si (KR); SEUNGHEE LEE, Yongin-si (KR); HO LIM, Yongin-si (KR)

(21) Appl. No.: 18/433,990

(22) Filed: Feb. 6, 2024

(30) Foreign Application Priority Data
Apr. 17, 2023 (KR) 10-2023-0050236

(51) Int. Cl. H10K 59/80; H10K 59/12; H10K 59/126; H10K 102/00

(52) U.S. Cl. CPC H10K 59/879; H10K 59/1201; H10K 59/126; H10K 2102/331; H10K 2102/351

(57) ABSTRACT

A display apparatus including a display panel, a light control layer provided directly on the display panel, and an anti-reflection layer provided on the light control layer is provided. The anti-reflection layer includes a plurality of inorganic layers, wherein the plurality of inorganic layers include a first inorganic layer including silicon nitride (SiNₓ), a second inorganic layer including silicon oxide (SiOₓ), a third inorganic layer including silicon nitride, and a fourth inorganic layer including silicon oxide. Each of the first inorganic layer and the third inorganic layer has a first refractive index, and each of the second inorganic layer and the fourth inorganic layer has a second refractive index less than the first refractive index.

### CROSS-REFERENCE TO RELATED APPLICATION

This application claims priority to and the benefit of Korean Patent Application No. 10-2023-0050236, filed on Apr. 17, 2023, in the Korean Intellectual Property Office, the entire content of which is incorporated herein by reference.

### BACKGROUND

### 1. Field

The present disclosure herein relates to a display apparatus and a method of manufacturing the same, and for example, to a display apparatus having improved visibility and/or reliability and a method of manufacturing the same.

### 2. Description of the Related Art

Various types (kinds) of display apparatuses are utilized to provide image information. The outer surface of such a display apparatus requires high surface hardness and impact resistance so as to protect the display apparatus from the external environment and to have reliability even in repeated use.

For example, when the display apparatus is exposed to external light sources such as one or more suitable types (kinds) of lighting and natural light, an image created inside by reflected light may not be clearly transmitted to a user, or the exposure to external light may cause headaches and/or eye fatigue to the user. For this reason, there is a strong demand or desire for reflection prevention or reduction.

### SUMMARY

One or more aspects of embodiments of the present disclosure are directed toward a display apparatus exhibiting excellent or suitable reflection prevention or reduction effects and improved reliability.

One or more aspects of embodiments of the present disclosure are directed toward a method of manufacturing a display apparatus having relatively low reflection characteristics and improved reliability.

One or more embodiments of the present disclosure provides a display apparatus including a display panel, a light control layer provided directly on the display panel, and an anti-reflection layer provided on the light control layer, wherein the anti-reflection layer includes a plurality of inorganic layers, wherein the plurality of inorganic layers include a first inorganic layer including (e.g., containing) silicon nitride (SiNₓ, x is an integer of 1 or more), a second inorganic layer including (e.g., containing) silicon oxide (SiOₓ, x is an integer of 1 or more), a third inorganic layer including (e.g., containing) silicon nitride, and a fourth inorganic layer including (e.g., containing) silicon oxide, wherein each of the first inorganic layer and the third inorganic layer has a first refractive index, and each of the second inorganic layer and the fourth inorganic layer has a second refractive index less (e.g., lower) than the first refractive index.

In one or more embodiments, the first refractive index may be about 1.80 to about 2.00 at a wavelength of about 550 nanometer (nm), and the second refractive index may be about 1.40 to about 1.50 at a wavelength of about 550 nm.

In one or more embodiments, a thickness of each of the first inorganic layer and the second inorganic layer may be about 10 nm to about 30 nm.

In one or more embodiments, a thickness of the third inorganic layer may be about 100 nm to about 150 nm, and a thickness of the fourth inorganic layer may be about 10 nm to about 30 nm.

In one or more embodiments, the first inorganic layer, the second inorganic layer, the third inorganic layer, and the fourth inorganic layer may be sequentially stacked.

In one or more embodiments, the plurality of inorganic layers includes a plurality of first inorganic layers and a plurality of second inorganic layers, and the plurality of first inorganic layers and the plurality of second inorganic layers may be alternately stacked on each other. For example, the stacked combination includes a first-first inorganic layer, a first-second inorganic layer, a second-first inorganic layer, a second-second inorganic layer, a third-first inorganic layer, a third-second inorganic layer, etc.

In one or more embodiments, the plurality of first inorganic layers may include a (1-1)-th inorganic layer and a (1-2)-th inorganic layer, and the plurality of second inorganic layers may include a (2-1)-th inorganic layer and a (2-2)-th inorganic layer, wherein the (1-1)-th inorganic layer, the (2-1)-th inorganic layer, the (1-2)-th inorganic layer, and the (2-2)-th inorganic layer may be sequentially stacked.

In one or more embodiments, the display apparatus may further include an overcoat layer provided between the light control layer and the anti-reflection layer, and the anti-reflection layer may come in contact with an upper surface of the overcoat layer.

In one or more embodiments, the first inorganic layer may be provided directly on the overcoat layer, the second inorganic layer may be provided directly on the first inorganic layer, and the third inorganic layer may be provided directly on the second inorganic layer.

In one or more embodiments, at least one of the first inorganic layer, the second inorganic layer, the third inorganic layer, or the fourth inorganic layer may be hydrogenated.

In one or more embodiments, the first inorganic layer may include (e.g., contain) hydrogenated silicon nitride (SiNₓ:H), and the second inorganic layer may include (e.g., contain) hydrogenated silicon oxide (SiOₓ:H).

In one or more embodiments, the plurality of inorganic layers may further include a fifth inorganic layer including (e.g., containing) silicon oxide, and the fifth inorganic layer, the first inorganic layer, the second inorganic layer, the third inorganic layer, and the fourth inorganic layer may be sequentially stacked.

In one or more embodiments, the anti-reflection layer may further include an organic layer provided on the plurality of inorganic layers, and an upper surface of the organic layer may include (e.g., define) an outermost surface of the anti-reflection layer.

In one or more embodiments, a refractive index of the organic layer may be about 1.25 to about 1.30, and a thickness of the organic layer may be about 60 nm to about 110 nm.

In one or more embodiments, the display apparatus may further include a color filter layer provided between the light control layer and the anti-reflection layer.

In one or more embodiments, the display panel may include a plurality of light-emitting elements configured to generate a first light, and the light control layer may include a first light control unit configured to transmit the first light, a second light control unit configured to convert the first light into a second light having a wavelength different from that (e.g., wavelength) of the first light, and a third light control unit configured to convert the first light into a third light having a wavelength different from each of those (e.g., wavelengths) of the first light and the second light.

In one or more embodiments, a reflectance of an upper surface of the anti-reflection layer may be about 2% or less.

In one or more embodiments of the present disclosure, a display apparatus includes: a display panel; a light control layer provided directly on the display panel; and an anti-reflection layer provided on the light control layer, wherein the anti-reflection layer includes a plurality of inorganic layers, wherein the plurality of inorganic layers include: a plurality of first inorganic layers having (e.g., each having) a first refractive index and including (e.g., each containing) silicon nitride (SiNₓ, x is an integer of 1 or more); and a plurality of second inorganic layers having (e.g., each having) a second refractive index less (e.g., lower) than the first refractive index and including (e.g., each containing) silicon oxide (SiOₓ, x is an integer of 1 or more), wherein the plurality of first inorganic layers and the plurality of second inorganic layers are alternately stacked by at least two layers. For example, the stacked combination includes at least a first-first inorganic layer, a first-second inorganic layer, a second-first inorganic layer, and a second-second inorganic layer, in order.

In one or more embodiments of the present disclosure, a method of manufacturing a display apparatus includes: forming a display panel; and forming an anti-reflection layer on the display panel, wherein the forming of the anti-reflection layer includes: forming a plurality of first inorganic layers having a first refractive index by providing a first reaction gas including (e.g., containing) SiH₄, N₂, and NH₃ on the display panel; and forming a plurality of second inorganic layers having a second refractive index less (e.g., smaller) than the first refractive index by providing a second reaction gas including (e.g., containing) SiH₄, and N₂O on the display panel, wherein the plurality of first inorganic layers and the plurality of second inorganic layers are alternately stacked by at least two layers.

In one or more embodiments of the present disclosure, the method of manufacturing the display apparatus may further include at least one of hydrogenating at least one selected from among the plurality of first inorganic layers by providing hydrogen (H₂) gas on the at least one selected from among the plurality of first inorganic layers or hydrogenating at least one selected from among the plurality of second inorganic layers by providing hydrogen (H₂) gas on the at least one selected from among the plurality of second inorganic layers.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a perspective view of a display apparatus according to one or more embodiments of the present disclosure;

FIG. 2 is a cross-sectional view of a display apparatus according to one or more embodiments of the present disclosure;

FIG. 3 is a plan view of a partial region of a display apparatus according to one or more embodiments of the present disclosure;

FIGS. 4A and 4B are cross-sectional views of a display apparatus according to one or more embodiments of the present disclosure;

FIGS. 5A-5E are cross-sectional views illustrating elements of a display apparatus according to one or more embodiments of the present disclosure;

FIGS. 6A and 6B are images of wet high temperature storage (WHTS) test results of a comparative example;

FIGS. 7A and 7B are images of wet high temperature storage (WHTS) test results of a display apparatus according to one or more embodiments of the present disclosure;

FIGS. 8A and 8B are flowcharts showing a method of manufacturing a display apparatus according to one or more embodiments of the present disclosure; and

FIGS. 9A-9E are cross-sectional views illustrating steps of a method of manufacturing a display apparatus according to one or more embodiments of the present disclosure.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

In this specification, it will be understood that when an element (or region, layer, portion, and/or the like) is referred to as being “on”, “connected to” or “coupled to” another element, it can be directly on, connected or coupled to the other element, or intervening elements may be present. On the contrary to this, when a layer, a film, a region, or a plate is referred to as being “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well.

Like reference numerals refer to like elements throughout, and duplicative descriptions thereof may be omitted (e.g., not be provided). In some embodiments, in the drawings, the thicknesses, ratios, and dimensions of elements are exaggerated for effective description of the technical contents.

As utilized herein, the term “and/or” includes any and all combinations that the associated configurations can define.

As utilized herein, the singular forms, “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

It will be understood that, although the terms first, second, and/or the like may be utilized herein to describe one or more suitable elements, these elements should not be limited by these terms. These terms are only utilized to distinguish one element from another element. For example, a first element could be termed a second element without departing from the scope of the present disclosure. Similarly, the second element may also be referred to as the first element. The terms of a singular form include plural forms unless otherwise specified.

In some embodiments, terms, such as “lower”, “above”, “upper” and/or the like, are utilized herein for ease of description to describe one element's relation to another element(s) as illustrated in the drawings. The described terms are relative concepts and are described based on the directions indicated in the drawings. It will be understood that the spatially relative terms are intended to encompass different orientations of the device in use or operation in addition to the orientation depicted in the drawings. For example, if the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

It will be understood that the terms “include,” “includes,” “including,” “comprise,” “comprises”, “comprising,” “have”, “has,” “having,” and/or the like when utilized in this specification, specify the presence of stated features, integers, steps, operations, elements, components and/or groups thereof, but do not preclude the presence or addition of one or more other features, integers, steps, operations, elements, components, and/or groups thereof.

In the present application, being “directly provided” may refer to that there is no layer, film, region, plate, and/or the like added between a part such as a layer, film, region, or plate and another part such as a layer, film, region, or plate. For example, being “directly provided” may refer to that no additional member such as an adhesive member is provided between two layers or two members.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

As utilized herein, the phrase “the plurality of first inorganic layers and the plurality of second inorganic layers are alternately stacked by on each other” refers to a stacked combination arranged with a first-first inorganic layer, a first-second inorganic layer, a second-first inorganic layer, a second-second inorganic layer, a third-first inorganic layer, a third-second inorganic layer, etc.

Hereinafter, embodiments of the present disclosure will be described with reference to the drawings.

### Display Apparatus

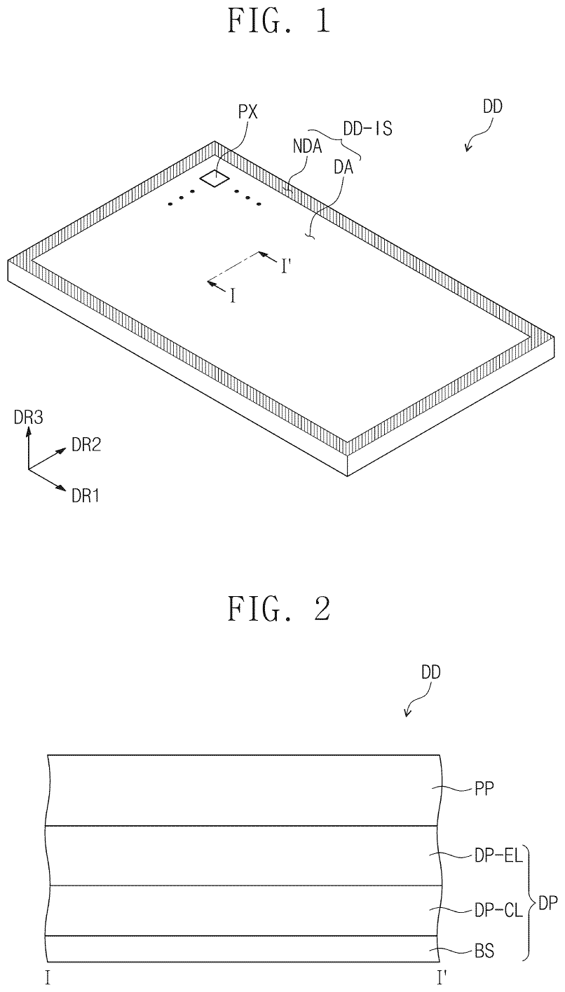

FIG. 1 is a perspective view of a display apparatus according to one or more embodiments of the present disclosure.

Referring to FIG. 1, the display apparatus DD according to one or more embodiments of the present disclosure may be activated according to an electrical signal. For example, the display apparatus DD may be a large-sized device such as a television, a monitor, or an external billboard. In some embodiments, the display apparatus DD may be a small- or medium-sized device such as a personal computer, a notebook computer, a personal digital terminal, a car navigation unit, a game machine, a smart phone, a tablet, or a camera. In some embodiments, these are merely presented as examples and the display apparatus DD may be employed in other electronic devices as long as they do not depart from the concept of the present disclosure.

The display apparatus DD may display an image (or video) through a display surface DD-IS. The display surface DD-IS may be parallel to a plane defined by first and second directions DR1 and DR2. The display surface DD-IS may include a display region DA and a non-display region NDA.

A pixel PX may be provided in the display region DA, but may be omitted (e.g., not be provided) in the non-display region NDA. The non-display region NDA may be defined along an edge of the display surface DD-IS. The non-display region NDA may surround the display region DA. However, the embodiment of the present disclosure is not limited thereto, and the non-display region NDA maybe be omitted (e.g., not be provided), or the non-display region NDA may be provided on only one side of the display region DA.

Although FIG. 1 illustrates the display apparatus DD having a flat display surface DD-IS, the embodiment of the present disclosure is not limited thereto. The display apparatus DD may include a curved display surface or a three-dimensional display surface. The three-dimensional display surface may include a plurality of display regions indicating different directions.

The thickness direction of the display apparatus DD may be parallel to a third direction DR3, which is a direction normal to a plane defined by the first and second directions DR1 and DR2. Directions indicated by the first to third directions DR1, DR2, and DR3 described in this specification are relative concepts and may be converted into other directions.

In this specification, the upper (or front) and lower (or rear) surfaces of members constituting the display apparatus DD may be defined based on the third direction DR3. More specifically, a surface relatively adjacent to the display surface DD-IS among two surfaces opposite to (e.g., facing) each other based on the third direction DR3 of one member may be defined as a front surface (or upper surface), and a surface relatively spaced and/or apart from the display surface DD-IS may be defined as a rear surface (or lower surface). In some embodiments, in this specification, upper and lower portions may be defined based on the third direction DR3, the upper portion may be defined in a direction towards the display surface DD-IS, and the lower portion may be defined in a direction away from the display surface DD-IS.

FIG. 2 is a cross-sectional view of the display apparatus according to one or more embodiments of the present disclosure. FIG. 2 is a cross-sectional view of the display apparatus DD according to one or more embodiments of the present disclosure, which corresponds to line I-I′ of FIG. 1.

Referring to FIG. 2, the display apparatus DD may include a display panel DP and an optical structure layer PP provided on the display panel DP. The display panel DP may include a display element layer DP-EL. The display element layer DP-EL includes a light-emitting element ED.

The optical structure layer PP may be provided on the display panel DP and control reflected light from the display panel DP by external light. The optical structure layer PP may include, for example, a color filter layer and an anti-reflection layer. A detailed description of the optical structure layer PP will be provided later.

In the display apparatus DD according to one or more embodiments of the present disclosure, the display panel DP may be a light-emitting display panel. For example, the display panel DP may be a light-emitting diode (LED) display panel, an organic electroluminescence display panel, or a quantum dot light-emitting display panel. However, the embodiment of the present disclosure is not limited thereto. The display panel DP may provide a first light. For example, the display panel DP may be to emit (e.g., configured to emit) blue light as a source light.

The light-emitting diode (LED) display panel may include (e.g., contain) a light-emitting diode, a light-emitting layer of the organic light-emitting display panel may include (e.g., contain) an organic light-emitting material, and a light-emitting layer of the quantum dot light-emitting display panel may include quantum dots, quantum rods, and/or the like. Hereinafter, the display panel DP included in the display apparatus DD according to one or more embodiments of this specification will be described as an organic electroluminescent display panel. However, the embodiment of the present disclosure is not limited thereto.

The display panel DP may include a base substrate BS, a circuit layer DP-CL provided on the base substrate BS, and a display element layer DP-EL provided on the circuit layer DP-CL.

The base substrate BS may be a member configured to provide a base surface on which the display element layer DP-EL is provided. The base substrate BS may be a glass substrate, a metal substrate, a plastic substrate, and/or the like. However, the embodiment of the present disclosure is not limited thereto, and the base substrate BS may be an inorganic layer, an organic layer, or a composite material layer. The base substrate BS may be a flexible substrate that may be easily bent or folded.

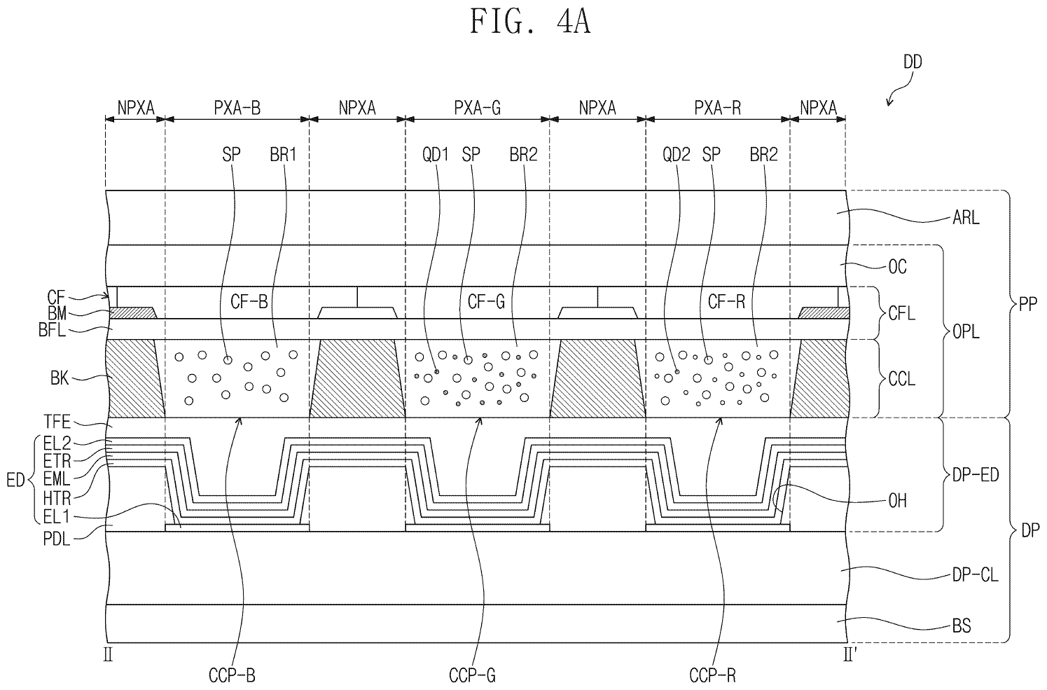

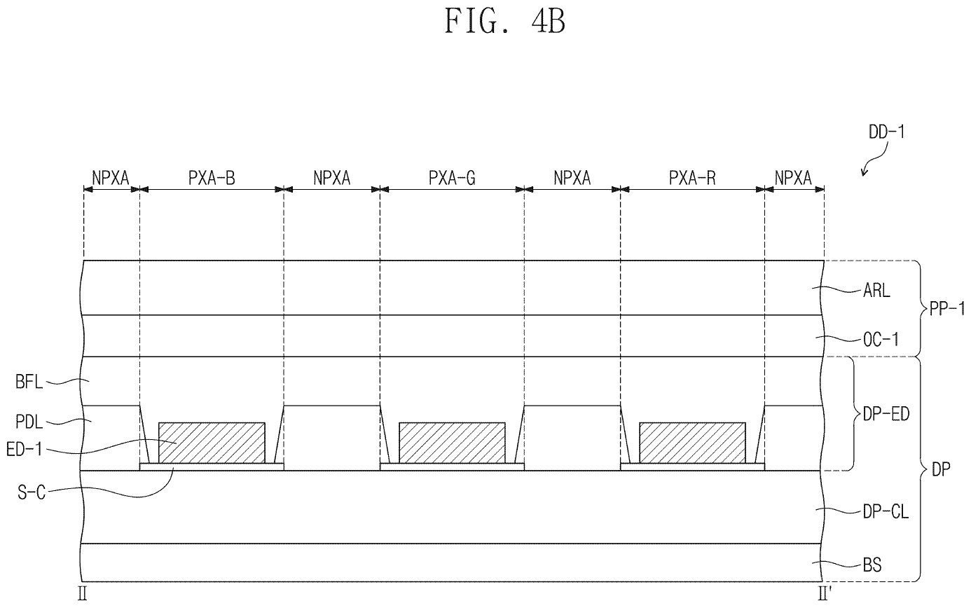

In one or more embodiments of the present disclosure, the circuit layer DP-CL may be provided on the base substrate BS, and the circuit layer DP-CL may include a plurality of transistors. Each of the transistors may include a control electrode, an input electrode, and an output electrode. For example, the circuit layer DP-CL may include a switching transistor and a driving transistor for driving the light-emitting element ED (see FIG. 4A) of the display element layer DP-EL.

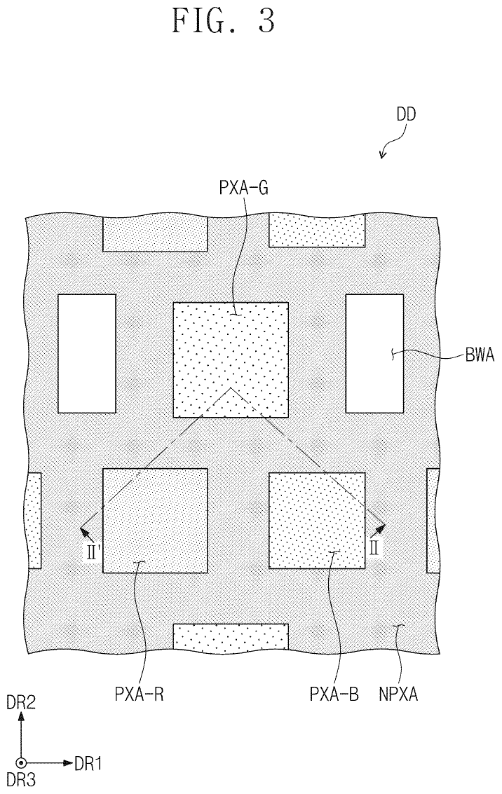

FIG. 3 is a plan view of a partial region of the display apparatus according to one or more embodiments of the present disclosure.

Referring to FIG. 3, the display apparatus DD according to one or more embodiments of the present disclosure may include a plane including three light-emitting regions PXA-B, PXA-G, and PXA-R and a bank well region BWA adjacent thereto. In one or more embodiments of the present disclosure, the three types (kinds) of light-emitting regions PXA-B, PXA-G, and PXA-R illustrated in FIG. 3 may be repeatedly provided throughout the display region DA (see FIG. 1).

A peripheral region NPXA is provided around each of the first to third light-emitting regions PXA-B, PXA-G, and PXA-R. The peripheral region NPXA sets boundaries between the first to third light-emitting regions PXA-B, PXA-G, and PXA-R. The peripheral region NPXA may surround (or be around) the first to third light-emitting regions PXA-B, PXA-G, and PXA-R. In the peripheral region NPXA, a structure such as a pixel defining film PDL (see FIG. 4A) configured to prevent or reduce color mixing between the first to third light-emitting regions PXA-B, PXA-G, and PXA-R may be provided.

FIG. 3 illustrates by example the first to third light-emitting regions PXA-B, PXA-G, and PXA-R having the same planar shape as each other and having planar areas different from each other, but the embodiment of the present disclosure is not limited thereto. Areas of at least two of the first to third light-emitting regions PXA-B, PXA-G, and PXA-R may be equal to each other. The areas of the first to third light-emitting regions PXA-B, PXA-G, and PXA-R may be set according to light-emitting colors. Among primary colors, a light-emitting region configured to emit green light may have the largest area and a light-emitting region configured to emit blue light may have the smallest area. However, the embodiment of the present disclosure is not limited to what is illustrated in FIG. 3, and the areas of the first to third light-emitting regions PXA-B, PXA-G, and PXA-R may be variously changed.

FIG. 3 illustrates the first to third light-emitting regions PXA-B, PXA-G, and PXA-R having a rectangular shape, but the embodiment of the present disclosure is not limited thereto. On a plane (or in a plan view), the first to third light-emitting regions PXA-B, PXA-G, and PXA-R may have different polygonal shapes (including substantially polygonal shapes) such as rhombuses or pentagons. In one or more embodiments of the present disclosure, the first to third light-emitting regions PXA-B, PXA-G, and PXA-R may have rectangular shapes (substantially rectangular shapes) with rounded corners on a plane.

FIG. 3 illustrates by example that the second light-emitting region PXA-G is provided in a first row and that the first light-emitting region PXA-B and the third light-emitting region PXA-R are provided in a second row, but without being limited thereto, the arrangement of the first to third light-emitting regions PXA-B, PXA-G, and PXA-R may be variously changed. For example, the first to third light-emitting regions PXA-B, PXA-G, and PXA-R may be arranged in a same row.

A bank well region BWA may be defined in the display region DA (see FIG. 1). The bank well region BWA may be a region in which a bank well is formed in order to prevent or reduce defects due to misplacement in the process of patterning a plurality of light control units CCP-B, CCP-G, and CCP-R (see FIG. 4A) included in a light control layer CCL (see FIG. 4A). For example, the bank well region BWA may be a region in which a bank well formed by partially removing barrier rib portions BK (see FIG. 4A) is defined.

FIG. 3 illustrates by example that two bank well regions BWA are defined to be adjacent to the second light-emitting region PXA-G, but without being limited thereto, the shape and arrangement of the bank well region BWA may be variously changed.

FIGS. 4A and 4B are cross-sectional views of display apparatuses according to one or more embodiments of the present disclosure. FIGS. 4A and 4B illustrate cross-sections corresponding to line II-II′ of FIG. 3.

In the display apparatuses DD and DD-1 according to one or more embodiments of the present disclosure, which are illustrated in FIGS. 3, 4A, and 4B, three light-emitting regions PXA-B, PXA-G, and PXA-R configured to emit blue light, green light, and red light are illustrated by example. For example, the display apparatuses DD and DD-1 according to one or more embodiments of the present disclosure may include a blue light-emitting region PXA-B, a green light-emitting region PXA-G, and a red light-emitting region PXA-R.

Referring to FIGS. 4A and 4B, the display apparatuses DD and DD-1 according to one or more embodiments of the present disclosure may include a display panel DP including light-emitting elements ED and ED-1 and optical structure layers PP and PP-1 provided on the display panel DP.

The display panel DP may include a base substrate BS, a circuit layer DP-CL provided on the base substrate BS, and a display element layer DP-EL. The display element layer DP-EL may include a pixel defining film PDL, a light-emitting element ED provided between the pixel defining films PDL or on the pixel defining film PDL, and an encapsulation layer TFE provided on the light-emitting element ED.

The display element layer DP-EL may include a pixel defining film PDL. Each of the light-emitting regions PXA-B, PXA-G, and PXA-R may be divided by the pixel defining film PDL. The peripheral region NPXA may be a region between neighboring light-emitting regions PXA-B, PXA-G, and PXA-R, and may correspond to the pixel defining film PDL. In some embodiments, in this specification, each of the light-emitting regions PXA-B, PXA-G, and PXA-R may correspond to a pixel. As illustrated in FIG. 4A, an organic layer such as a light-emitting layer EML included in the light-emitting element ED may be provided as a common layer so as to overlap all of the light-emitting regions PXA-B, PXA-G, and PXA-R and the peripheral region NPXA. Alternatively, in some embodiments, the light-emitting layer EML of the light-emitting element ED may be provided and divided (or patterned) in an opening OH defined by the pixel defining film PDL.

The pixel defining film PDL may be formed of a polymer resin. For example, the pixel defining film PDL may be formed by including (e.g., containing) a polyacrylate-based resin or a polyimide-based resin. In some embodiments, the pixel defining film PDL may be formed by further including (e.g., containing) an inorganic material in addition to the polymer resin. In some embodiments, the pixel defining film PDL may be formed by including (e.g., containing) a light absorbing material or may be formed by containing a black pigment or black dye. The pixel defining film PDL formed by including (e.g., containing) the black pigment or black dye may implement a black pixel defining film. When the pixel defining film PDL is formed, carbon black and/or the like may be utilized as a black pigment or black dye, but the embodiment of the present disclosure is not limited thereto.

The pixel defining film PDL may be formed of an inorganic material. For example, the pixel defining film PDL may be formed by including (e.g., containing) silicon nitride (SiNₓ), silicon oxide (SiOₓ), silicon oxynitride (SiOₓN_{y}), and/or the like (where each of x and y is an integer of 1 or more. For example, each of x and y is an integer of 1 to 4). The pixel defining film PDL may define the light-emitting regions PXA-B, PXA-G, and PXA-R. The light-emitting regions PXA-B, PXA-G, and PXA-R and the peripheral region NPXA may be distinguished by the pixel defining film PDL.

Referring to FIG. 4A, the display element layer DP-EL may include a light-emitting element ED partially provided on the pixel defining film PDL. In one or more embodiments of the present disclosure, the display apparatus DD may include a light-emitting element ED, and the light-emitting element ED may include a light-emitting layer EML. The light-emitting element ED according to one or more embodiments of the present disclosure includes a first electrode EL1, a second electrode EL2 facing the first electrode EL1, and a plurality of functional layers provided between the first electrode EL1 and the second electrode EL2 and including a light-emitting layer EML. The plurality of functional layers may include a hole transport region HTR

provided between the first electrode EL1 and the light-emitting layer EML and an electron transport region ETR provided between the light-emitting layer EML and the second electrode EL2. In some embodiments, in the drawings, in one or more embodiments of the present disclosure, an element capping layer may be further provided on the second electrode EL2.

Each of the hole transport region HTR and the electron transport region ETR may include a plurality of sub-functional layers. For example, the hole transport region HTR may include a hole injection layer and a hole transport layer as sub-functional layers, and the electron transport region ETR may include an electron injection layer and an electron transport layer as sub-functional layers. In some embodiments, the embodiment of the present disclosure is not limited thereto, and the hole transport region HTR may further include an electron blocking layer and/or the like as a sub-functional layer, and the electron transport region ETR may further include a hole blocking layer and/or the like as a sub-functional layer.

The first electrode EL1 has conductivity (e.g., is a conductor). The first electrode EL1 may be formed of a metal alloy and/or a conductive compound. The first electrode EL1 may be an anode. The first electrode EL1 may be a pixel electrode. The first electrode EL1 may be a reflective electrode. However, the embodiment of the present disclosure is not limited thereto, and the first electrode EL1 may be a transmissive electrode, a semi-transmissive electrode, and/or the like. When the first electrode EL1 is a semi-transmissive electrode or a reflective electrode, the first electrode EL1 may include (e.g., contain) Ag, Mg, Cu, Al, Pt, Pd, Au, Ni, Nd, Ir, Cr, Li, Ca, LiF/Ca, LiF/Al, Mo, Ti, and/or a compound and/or a mixture thereof (e.g., a mixture of Ag and Mg). In some embodiments, the first electrode EL1 may have a structure having a plurality of layers including a reflective film or a semi-transmissive film formed of the materials examples of which are provided herein and a transparent conductive film formed of indium tin oxide (ITO), indium zinc oxide (IZO), zinc oxide (ZnO), indium tin zinc oxide (ITZO), and/or the like. For example, the first electrode EL1 may be a multi-layered metal film and may have a structure in which the metal films of ITO/Ag/ITO are stacked.

The hole transport region HTR is provided on the first electrode EL1. The hole transport region HTR may include a hole injection layer and a hole transport layer. The hole transport region HTR may have a single-layered structure made of a single material, a single-layered structure made of a plurality of different materials, or a multi-layered structure having a plurality of layers made of a plurality of different materials.

The hole transport region HTR may be formed by utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The hole transport region HTR may include (e.g., contain) a carbazole-based derivative such as at least one of N-phenylcarbazole and polyvinylcarbazole, a fluorene-based derivative, TPD (N,N′-bis(3-methylphenyl)-N,N′-diphenyl-[1,1′-biphenyl]-4,4′-diamine), a triphenylamine-based derivative such as TCTA (4,4′,4″-tris(N-carbazolyl) triphenylamine), NPD (N,N′-di(naphthalene-1-yl)-N,N′-diphenyl-benzidine), TAPC (4,4′-Cyclohexylidene bis [N,N-bis(4-methylphenyl)benzenamine]), HMTPD (4,4′-Bis [N,N′-(3-tolyl)amino]-3,3′-dimethylbiphenyl), and/or mCP (1,3-Bis(N-carbazolyl)benzene).

The hole transport region HTR may have a thickness of about 5 nm to about 1,500 nm, for example, about 10 nm to about 500 nm. When the thickness of the hole transport region HTR satisfies the aforementioned range, it is possible to obtain satisfactory hole transport characteristics without a substantial increase in driving voltage.

The light-emitting layer EML is provided on the hole transport region HTR. The light-emitting layer EML may include a host and a dopant. In one or more embodiments of the present disclosure, the light-emitting layer EML may include (e.g., contain) an organic light-emitting material as a dopant material. Alternatively, in some embodiments, the light-emitting layer EML may include (e.g., contain) quantum dots as a dopant material. In one or more embodiments of the present disclosure, the light-emitting layer EML may further include (e.g., contain) an organic host material in addition to the dopant material. In the display panel DP according to one or more embodiments of the present disclosure, the light-emitting layer EML included in the light-emitting element ED may be to emit (e.g., configured to emit) blue light having a central wavelength of about 420 nm to about 480 nm.

In the light-emitting element ED according to one or more embodiments of the present disclosure, the electron transport region ETR is provided on the light-emitting layer EML. The electron transport region ETR may include at least one of an electron transport layer or an electron injection layer, but the embodiment of the present disclosure is not limited thereto.

The electron transport region ETR may have a single-layered structure made of a single material, a single-layered structure made of a plurality of different materials, or a multi-layered structure having a plurality of layers made of a plurality of different materials. For example, the electron transport region ETR may have a single-layered structure having an electron injection layer or an electron transport layer, or may have a single-layered structure composed of an electron injection material and an electron transport material. The thickness of the electron transport region ETR may be, for example, about 20 nm to about 150 nm.

The electron transport region ETR may be formed by utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The electron transport region ETR may contain, for example, at least one of an anthracene-based compound, Alq₃ (Tris(8-hydroxyquinolinato)aluminum), 1,3,5-tri [(3-pyridyl)-phen-3-yl]benzene, 2,4,6-tris(3′-(pyridin-3-yl) biphenyl-3-yl)-1,3,5-triazine, DPEPO (bis [2-(diphenylphosphino)phenyl]ether oxide), 2-(4-(N-phenylbenzoimidazolyl-1-ylphenyl)-9,10-dinaphthylanthracene, TPBi (1,3,5-Tri (1-phenyl-1H-benzo[d]imidazol-2-yl)phenyl), and/or a mixture thereof. In some embodiments, the electron transport region ETR may include (e.g., contain) a metal halide such as LiF, NaCl, CsF, RbCl, or RbI, a lanthanide metal such as Yb, a metal oxide such as Li₂O or BaO, lithium quinolate (Liq), and/or the like.

The second electrode EL2 is provided on the electron transport region ETR. The second electrode EL2 may be a common electrode or a cathode. The second electrode EL2 may be a transmissive electrode, a semi-transmissive electrode, or a reflective electrode. When the second electrode EL2 is a transmissive electrode, the second electrode EL2 may include (e.g., be composed of) a transparent metal oxide such as indium tin oxide (ITO), indium zinc oxide (IZO), zinc oxide (ZnO), or indium tin zinc oxide (ITZO). When the second electrode EL2 is a semi-transmissive electrode or a reflective electrode, the second electrode EL2 may include (e.g., contain) at least one of Ag, Mg, Cu, Al, Pt, Pd, Au, Ni, Nd, Ir, Cr, Li, Ca, LiF/Ca, LiF/Al, Mo, Ti, Yb, and/or a compound and/or mixture thereof. In some embodiments, the second electrode EL2 may have a multi-layered structure including a reflective film or semi-transmissive film formed of the described material and a transparent conductive film formed of indium tin oxide (ITO), indium zinc oxide (IZO), zinc oxide (ZnO), indium tin zinc oxide (ITZO), and/or the like.

In one or more embodiments, the second electrode EL2 may be connected to an auxiliary electrode. When the second electrode EL2 is connected to the auxiliary electrode, resistance of the second electrode EL2 may be reduced.

Referring to FIGS. 3, 4A and 4B, in the display apparatus DD according to one or more embodiments of the present disclosure, the areas of the light-emitting regions PXA-B, PXA-G, and PXA-R may be different from each other. In some embodiments, in this specification, the term “area” may refer to an area when viewed on a plane defined by the first and second directions DR1 and DR2. For example, the light-emitting regions PXA-B, PXA-G, and PXA-R may have different areas according to light-emitting colors. In this case, the areas may refer to areas when viewed on a plane defined by the first and second directions DR1 and DR2. For example, in the display apparatus DD according to one or more embodiments of the present disclosure, the blue light-emitting region PXA-B configured to emit blue light may have the smallest area, and the green light-emitting region PXA-G configured to generate green light may have the largest area. However, the embodiment of the present disclosure is not limited thereto, and the light-emitting regions PXA-B, PXA-G, and PXA-R may be to emit (e.g., configured to emit) another color light other than blue light, green light, and red light, the light-emitting regions PXA-B, PXA-G, PXA-R may have the same area as one another, or the light-emitting regions PXA-B, PXA-G, and PXA-R may be provided with an area ratio different from the area ratio illustrated in FIG. 3. In some embodiments, the light-emitting regions PXA-B, PXA-G, and PXA-R may have one or more suitable polygonal or circular shapes different from those illustrated in FIG. 3, and the arrangement structure of the light-emitting regions is not limited either. For example, in one or more embodiments of the present disclosure, the light-emitting regions PXA-B, PXA-G, and PXA-R may have a PENTILE® arrangement shape or a Diamond Pixel® arrangement shape (PENTILE® and Diamond Pixel® are registered trademarks owned by Samsung Display Co., Ltd.)

Referring to FIG. 4A, the encapsulation layer TFE may be provided on and cover the light-emitting element ED. The encapsulation layer TFE may be a single layer or a plurality of layers stacked on each other. The encapsulation layer TFE may be a thin film encapsulation layer. The encapsulation layer TFE protects the light-emitting element ED. The encapsulation layer TFE may cover the upper surface of the second electrode EL2 provided in the opening OH and fill the opening OH.

Referring to FIGS. 4A and 4B, the display apparatuses DD and DD-1 according to one or more embodiments of the present disclosure may include optical structure layers PP and PP-1. The optical structure layers PP and PP-1 may have a function of changing at least a portion of the wavelength of light provided from the display panel DP or preventing or reducing color mixing between adjacent light-emitting regions. In some embodiments, the optical structure layers PP and PP-1 may block or reduce external light provided from the outside of the display apparatuses DD and DD-1 to the display panel DP. The optical structure layers PP and PP-1 may have an anti-reflection function to minimize or reduce reflection by external light.

Referring to FIG. 4A, in the display apparatus DD according to one or more embodiments of the present disclosure, the optical structure layer PP includes an optical layer OPL provided on the display panel DP and an anti-reflection layer ARL provided on the optical layer OPL. The optical layer OPL may include a light control layer CCL, a color filter layer CFL, and an overcoat layer OC which are sequentially stacked.

The light control layer CCL may include a light converter. The light converter may be a quantum dot, a phosphor, and/or the like. The light converter may convert the wavelength of received light and emit the converted light. For example, the light control layer CCL may be a layer at least partially containing a quantum dot or a phosphor.

The light control layer CCL may be provided on the display panel DP. The light control layer CCL may be provided on the display panel DP with a capping layer CPL interposed therebetween. The light control layer CCL may include a plurality of barrier rib portions BK provided to be spaced and/or apart from each other and light control units CCP-B, CCP-G, and CCP-R provided between the barrier rib portions BK. The barrier rib portion BK may be formed by containing a polymer resin and a liquid repellent additive. The barrier rib portion BK may be formed by containing a light absorbing material or a pigment or dye. For example, the barrier rib portion BK may be formed by containing a black pigment or black dye to implement a black barrier rib portion. When the black barrier rib portion is formed, carbon black and/or the like may be utilized as a black pigment or black dye, but the embodiment of the present disclosure is not limited thereto.

The light control layer CCL may include a first light control unit CCP-B that transmits a first light which is a source light provided from the light-emitting element ED, a second light control unit CCP-G that converts the first light into a second light, and a third light control unit CCP-R that converts the first light into a third light. The second light may have a longer wavelength region than the first light, and the third light may have a longer wavelength region than the first light and the second light. For example, the first light may have a light-emitting wavelength of about 410 nm to about 480 nm, the second light may have a light-emitting wavelength of about 500 nm to about 600 nm, and the third light may have a light-emitting wavelength of about 620 nm to about 700 nm. The first light may be blue light, the second light may be green light, and the third light may be red light.

A light-emitting body may be included in each of the second light control unit CCP-G and the third light control unit CCP-R. The light-emitting body may be a particle that converts the wavelength of incident light and emits light having a different wavelength. In one or more embodiments of the present disclosure, the light-emitting body included in the second light control unit CCP-G and the third light control unit CCP-R may be a quantum dot or a phosphor. The second light control unit CCP-G may include a first quantum dot QD1 that converts the first light into the second light, and the third light control unit CCP-R may include a second quantum dot QD2 that converts the first light into the third light. The first light control unit CCP-B is a transmission unit that transmits the wavelength of the first light without converting the first light and may not include (e.g., may exclude) a separate light-emitting body. Without being limited thereto, however, a light-emitting body such as a quantum dot, which converts light incident on the first light control unit CCP-B into the first light, may be included.

The quantum dot may be selected from among a group II-VI compound, a group I-II-VI compound, a group II-IV-VI compound, a group I-II-IV-VI compound, a group III-VI compound, a group I-III-VI compound, a group III-V compound, a group III-II-V compound, a group II-IV-V compound, a group IV-VI compound, a group IV element, a group IV compound, and a combination thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgZnTe, HgZnS, HgZnSe, HgZnTe, MgZnS, MgZnS and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. In some embodiments, the group II-VI compound may further include a group I metal and/or a group IV element. The group I-II-VI compound may be selected from CuSnS or CuZnS, and the group II-IV-VI compound may be selected from ZnSnS and/or the like. The group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

The group III-VI compound may include a binary compound such as In₂S₃ or In₂Se₃, a ternary compound such as InGaS₃ or InGaSe₃, or any combination thereof.

The group I-III-VI compound may be selected from ternary compounds selected from the group consisting of AgInS, AgInS₂, CuInS, CuInS₂, AgGaS₂, CuGaS₂ CuGaO₂, AgGaO₂, AgAlO₂ and a mixture thereof, or quaternary compounds such as AgInGaS₂, and CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the group III-V compound may further include a group II metal. For example, InZnP and/or the like may be selected as a group III-II-V compound.

The group II-IV-V compound may be a ternary compound selected from the group consisting of ZnSnP, ZnSnP₂, ZnSnAs₂, ZnGeP₂, ZnGeAs₂, CdSnP₂, CdGeP₂, and a mixture thereof.

The group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The group IV element may be selected from the group consisting of Si, Ge, and a mixture thereof. The group IV compound may be a binary compound selected from the group consisting of SiC, SiGe, and a mixture thereof.

Each element included in the multi-element compounds such as the binary element compounds, the ternary element compounds, and the quaternary element compounds may be present in a particle at a substantially uniform concentration or a non-substantially uniform concentration. For example, the chemical formulas refer to the types (kinds) of elements included in the compounds, and the ratios of elements in the compounds may be different from each other. For example, AgInGaS₂ may refer to AgInₓGa₁₋ₓS₂ (x is a real number between 0 and 1).

In this case, the binary compounds, the ternary compounds, or the quaternary compounds may be present in a particle at a substantially uniform concentration, or they may be present in a same particle by being divided into states in which the concentration distributions thereof are partially different from one another. In some embodiments, the quantum dots may have a core/shell structure in which one quantum dot surrounds another quantum dot. The core/shell structure may have a concentration gradient in which the concentration of an element present in the shell gradually decreases toward the core.

In some embodiments of the present disclosure, the quantum dots may have a core-shell structure including: a core including a nanocrystal described herein; and a shell around (e.g., surrounding) the core. The shell of the quantum dots may serve as a protective layer for maintaining semiconductor characteristics by preventing or reducing the chemical modification of the core and/or as a charging layer for imparting electrophoretic characteristics to the quantum dots. The shell may be single-layered or multi-layered. Examples of the shell of the quantum dots may include a metal or non-metal oxide, a semiconductor compound, or a combination thereof.

The shell may include (e.g., contain) a material different from that of the core. For example, the core may include a first semiconductor nanocrystal, and the shell may include a second semiconductor nanocrystal different from the first semiconductor nanocrystal. In some embodiments, the shell may include (e.g., contain) a metal or non-metal oxide. The shell may include (e.g., contain) a metal or non-metal oxide, a semiconductor nanocrystal, or a combination thereof.

The shell may be made of a single material, but may be formed to have a concentration gradient. For example, the shell may have a concentration gradient in which the concentration of the second semiconductor nanocrystal present in the shell gradually decreases and the concentration of the first semiconductor nanocrystal included in the core gradually increases as the shell is closer to the core. In some embodiments, the shell may have a structure having a plurality of layers including materials different from each other.

For example, examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the embodiment of the present disclosure is not limited thereto.

In some embodiments, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

The quantum dot may have a full width of half maximum (FWHM) of a light-emitting wavelength spectrum of about 45 nm or less, about 40 nm or less, or more about 30 nm or less, and within those ranges, it is possible to improve color purity or color reproducibility. In some embodiments, because light emitted through the quantum dot is emitted in all directions, a wide viewing angle may be improved.

In some embodiments, the shape of the quantum dot is not particularly limited to those generally utilized in the art, but more specifically, a shape such as a spherical, pyramidal, multi-armed, or cubic nanoparticle, nanotube, nanowire, nanofiber, and nanoplate particle may be utilized.

Because an energy band gap may be controlled or selected by adjusting the size of the quantum dot or the ratio of elements in a quantum dot compound, light of one or more suitable wavelengths may be obtained from a quantum dot light-emitting layer. Therefore, by utilizing the quantum dot described herein (e.g., utilizing quantum dots of different sizes or different element ratios in the quantum dot compound), a light-emitting element configured to emit light of one or more suitable wavelengths may be implemented. For example, the control of the size of the quantum dot or the ratio of elements in the quantum dot compound may be selected so as to emit red light, green light, and/or blue light. In some embodiments, the quantum dots may be configured to emit white light by combining light of one or more suitable colors. In some embodiments, when the quantum dots have one or more suitable light-emitting colors such as a blue color, a red color, and/or a green color, the quantum dots having different light-emitting colors may have different core materials.

The quantum dot may control the color of emitted light according to the particle size thereof, and accordingly, the quantum dot may have one or more suitable light-emitting colors such as blue, red, and/or green. As the particle size of the quantum dot decreases, light having a shorter wavelength region may be emitted. For example, the particle size of the quantum dot that emits green light may be smaller than the particle size of the quantum dot that emits red light, and the particle size of the quantum dot that emits blue light may be smaller than the particle size of the quantum dot that emits green light.

Each of the plurality of light control units CCP-B, CCP-G, and CCP-R included in the light control layer CCL may further include a scatterer SP. The first light control unit CCP-B may include only the scatterer SP, the second light control unit CCP-G may include the first quantum dot QD1 and the scatterer SP, and the third light control unit CCP-R may include the second quantum dot QD2 and the scatterer SP.

The scatterer SP may be an inorganic particle. For example, the scatterer SP may include (e.g., contain) at least any one of TiO₂, ZnO, Al₂O₃, SiO₂, or hollow silica. The scatterer SP may include (e.g., contain) any one of TiO₂, ZnO, Al₂O₃, SiO₂ and/or hollow silica, or may be a mixture of two or more materials selected from among TiO₂, ZnO, Al₂O₃, SiO₂, and hollow silica.

Each of the first light control unit CCP-B, the second light control unit CCP-G, and the third light control unit CCP-R may include (e.g., contain) base resins BR1, BR2, and BR3 that disperse the quantum dots QD1 and QD2 and the scatterer SP. In one or more embodiments of the present disclosure, the first light control unit CCP-B may include (e.g., contain) the scatterer SP dispersed in the first base resin BR1, the second light control unit CCP-G may include (e.g., contain) the first quantum dot QD1 and the scatterer SP dispersed in the second base resin BR2, and the third light control unit CCP-R may include (e.g., contain) the second quantum dot QD2 and the scatterer SP dispersed in the third base resin BR3. The base resins BR1, BR2, and BR3 are each a composition (e.g., media), in which the quantum dots QD1 and QD2 and the scatterer SP are dispersed, and may be made of one or more suitable resin compositions that are generally referred to as binders. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments of the present disclosure, the first base resin BR1, the second base resin BR2, and the third base resin BR3 may be the same as or different from each other.

In the display apparatus DD according to one or more embodiments of the present disclosure, the optical layer OPL may include an overcoat layer OC and a color filter layer CFL.

The color filter layer CFL may include color filters CF. The color filter layer CFL may include a first color filter CF-B that transmits a portion of a source light, a second color filter CF-G that transmits a second light, and a third color filter CF-R that transmits a third light. In some embodiments, the color filter layer CFL may include a first color filter CF-B that transmits blue light, a second color filter CF-G that transmits green light, and a third color filter CF-R that transmits red light. In one or more embodiments of the present disclosure, the first color filter CF-B may be a blue filter, the second color filter CF-G may be a green filter, and the third color filter CF-R may be a red filter.

Each of the color filters CF includes (e.g., contains) a polymer photosensitive resin and a colorant. The first color filter CF-B may include (e.g., contain) a blue colorant, the second color filter CF-G may include (e.g., contain) a green colorant, and the third color filter CF-R may include (e.g., contain) a red colorant. The first color filter CF-B may include (e.g., contain) a blue pigment or a blue dye, the second color filter CF-G may include (e.g., contain) a green pigment or a green dye, and the third color filter CF-R may include (e.g., contain) a red pigment or a red dye.

The first to third color filters CF-B, CF-G, and CF-R may be respectively provided to correspond to the first light-emitting region PXA-B, the second light-emitting region PXA-G, and the third light-emitting region PXA-R. In some embodiments, the first to third color filters CF-B, CF-G, and CF-R may be respectively provided to correspond to the first to third light control units CCP-B, CCP-G, and CCP-R.

In some embodiments, the plurality of color filters CF-B, CF-G, and CF-R configured to transmit light of different colors may be provided to overlap each other, while corresponding to the peripheral region NPXA provided between light-emitting regions PXA-B, PXA-G, and PXA-R. The plurality of color filters CF-B, CF-G, and CF-R may be provided to overlap each other in the third direction DR3, which is the thickness direction, so as to demarcate boundaries between adjacent light-emitting regions PXA-B, PXA-G, and PXA-R. Accordingly, as the light-blocking effect of external light increases, it is possible to have a function as a black matrix. An overlapping structure of the plurality of color filters CF-B, CF-G, and CF-R may also have a function of preventing or reducing color mixing.

In some embodiments, unlike the above, the color filter layer CFL may include a light-blocking portion which demarcates boundaries between adjacent color filters CF-B, CF-G, and CF-R. The light-blocking portion may be formed of a blue filter or may be formed by including (e.g., containing) an organic light-blocking material or an inorganic light-blocking material including a black pigment or a black dye.

In some embodiments, the embodiment of the present disclosure is not limited thereto, and the first color filter CF-B may not include (e.g., contain) a pigment or a dye. The first color filter CF-B may include (e.g., contain) a polymer photosensitive resin and may not include (e.g., contain) a pigment or a dye. The first color filter CF-B may be transparent. The first color filter CF-B may be formed of a transparent photosensitive resin.

The color filter layer CFL may further include a buffer layer BFL. For example, the buffer layer BFL may be a protective layer configured to protect the filters CF-B, CF-G, and CF-R. The buffer layer BFL may be an inorganic material layer including (e.g., containing) at least one inorganic material of silicon nitride, silicon oxide, and silicon oxynitride. The buffer layer BFL may be formed of a single layer or a plurality of layers.

In one or more embodiments of the present disclosure illustrated in FIG. 4A, the first to third color filters CF-B, CF-G, and CF-R may be demarcated by the light-blocking portion BM and may not overlap each other on a plane. In some embodiments, in one or more embodiments of the present disclosure, the first to third color filters CF-B, CF-G, and CF-R may be respectively provided to correspond to the blue light-emitting region PXA-B, the green light-emitting region PXA-G, and the red light-emitting region PXA-R. However, the embodiment of the present disclosure is not limited thereto, and two or more of the first color filter CF-B, the second color filter CF-G, and the third color filter CF-R of the color filter layer CFL may be provided to overlap each other in the peripheral region NPXA.

In some embodiments, a polarization layer may be further included in the optical layer OPL of the display apparatus DD according to one or more embodiments of the present disclosure. The polarization layer may block or reduce external light provided to the display panel DP from the outside. The polarization layer may block or reduce a portion of external light. When the display apparatus DD includes the polarization layer, the color filter layer CFL may be omitted (e.g., not be provided).

In some embodiments, the polarization layer may reduce reflected light generated from the display panel DP by external light. For example, the polarization layer may perform a function of blocking reflected light when light provided from the outside of the display apparatus DD is incident on the display panel DP and then is emitted. The polarization layer may be a circular polarizer having an anti-reflection function or may include a linear polarizer and a N/4 retarder. In some embodiments, the polarization layer may be provided on the overcoat layer OC to be exposed, or the polarization layer may be provided the overcoat layer OC.

The overcoat layer OC may be provided on the color filter layer CFL. The overcoat layer OC may include an organic layer. The overcoat layer OC may include (e.g., contain) an organic material having high strength and high planarization properties. The overcoat layer OC may provide a flat upper surface. In some embodiments, the overcoat layer OC may serve as an upper base layer configured to provide a reference surface on the color filter layer CFL. The overcoat layer OC may be a member configured to provide a base surface on which an anti-reflection layer ARL provided thereabove is provided. The overcoat layer OC may be an inorganic layer, an organic layer, or a composite material layer. However, the embodiment of the present disclosure is not limited thereto, and the overcoat layer OC may be a glass substrate, a metal substrate, a plastic substrate, and/or the like.

An anti-reflection layer ARL is provided on the overcoat layer OC. The anti-reflection layer ARL may be provided directly on the overcoat layer OC. For example, the anti-reflection layer ARL may contact (e.g., come in contact with) the upper surface of the overcoat layer OC. The anti-reflection layer ARL may block or reduce external light because it has a low reflectance. The anti-reflection layer ARL may have a plurality of layers having different refractive indices and, therefore, effectively block or reduce external light through destructive interference. The reflectance of the upper surface of the anti-reflection layer ARL may be about 2% or less. In the visible light range of about 430 nm to about 780 nm, the reflectance of the upper surface of the anti-reflection layer ARL may be about 2% or less. At a wavelength of about 550 nm, the reflectance of the upper surface of the anti-reflection layer ARL may be about 2% or less.

In the display apparatuses DD and DD-1 according to one or more embodiments of the present disclosure, a separate layer may be omitted (e.g., not be provided) on the anti-reflection layer ARL. For example, the anti-reflection layer ARL may be the outermost layer provided at the uppermost portion of the display apparatuses DD and DD-1. The upper surface of the anti-reflection layer ARL may define the outermost and uppermost surface of the display apparatuses DD and DD-1. The anti-reflection layer ARL may be the outermost layer of the display apparatuses DD and DD-1.

In the display apparatus DD according to one or more embodiments of the present disclosure, the light control layer CCL and the color filter layer CFL may be provided by utilizing the upper surface of the encapsulation layer TFE as a base surface. For example, the light control units CCP-B, CCP-G, and CCP-R of the light control layer CCL may be formed on the display panel DP in a substantially continuous process, and filters CF-B, CF-G, and CF-R of the color filter layer CFL may be sequentially formed on the light control layer CCL through a substantially continuous process. The light control layer CCL may be formed by utilizing the upper surface of the encapsulation layer TFE as a base surface which is provided on the display panel DP. The color filter layer CFL may be formed by utilizing the upper surface of the light control layer CCL as a base surface.

In the color filter layer CFL according to one or more embodiments of the present disclosure, the light-blocking portion BM may be a black matrix. The light-blocking portion BM may be formed by including (e.g., containing) an organic light-blocking material or an inorganic light-blocking material which includes a black pigment or a black dye. The light-blocking portion BM may prevent or reduce a light leakage phenomenon and demarcate boundaries between adjacent color filters CF-B, CF-G, and CF-R.

Referring to FIG. 4B, the display panel DP included in the display apparatus DD-1 according to one or more embodiments of the present disclosure includes a light-emitting element ED-1, and the light-emitting element ED-1 may be a micro LED element (in micrometer scale) or a nano LED element (in nanometer scale). The light-emitting element ED-1 may be electrically connected to a contact portion S-C, and the length and width of the light-emitting element ED-1 may be between hundreds of nanometers and hundreds of micrometers. The light-emitting element ED-1 may be an LED element including an active layer and at least one semiconductor material layer. The light-emitting element ED-1 may further include an insulating layer. The light-emitting element ED-1 may be patterned and provided so as to overlap each of the light-emitting regions PXA-B, PXA-G, and PXA-R. The display panel DP may include a buffer layer BFL provided on the light-emitting element ED-1. The buffer layer BFL may be provided on and cover the light-emitting element ED-1.

Compared to the display apparatus DD according to one or more embodiments of the present disclosure illustrated in FIG. 4A, the display apparatus DD-1 according to one or more embodiments of the present disclosure illustrated in FIG. 4B excludes (e.g., does not include) a light control layer and a color filter layer in the optical structure layer PP-1. For example, the display apparatus DD-1 according to one or more embodiments of the present disclosure may include an overcoat layer OC-1 provided on the buffer layer BFL, and an anti-reflection layer ARL may be provided on the overcoat layer OC-1. The overcoat layer OC-1 may include an organic layer. The overcoat layer OC-1 may include (e.g., contain) an organic material having high strength and high planarization properties. The overcoat layer OC-1 may provide a flat upper surface and a reference surface on which the anti-reflection layer ARL is provided. The overcoat layer OC-1 may be an inorganic layer, an organic layer, or a composite material layer. However, the embodiment of the present disclosure is not limited thereto, and the overcoat layer OC-1 may be a glass substrate, a metal substrate, a plastic substrate, and/or the like. In some embodiments, in the display apparatus DD-1 according to one or more embodiments of the present disclosure illustrated in FIG. 4B, any one of the buffer layer BFL and the overcoat layer OC-1 may be omitted (e.g., not be provided).

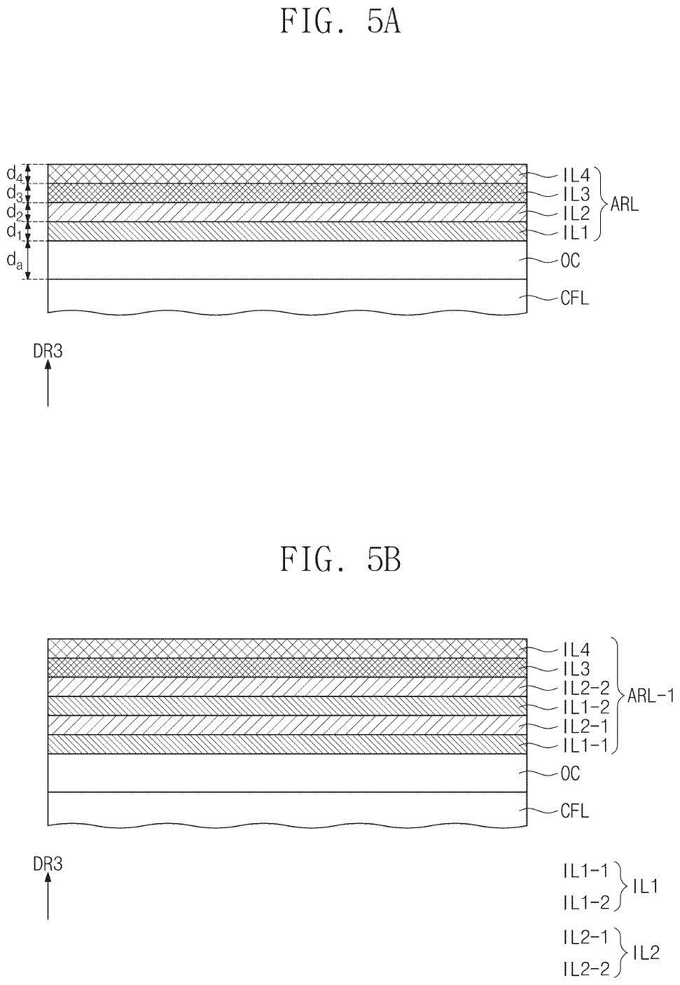

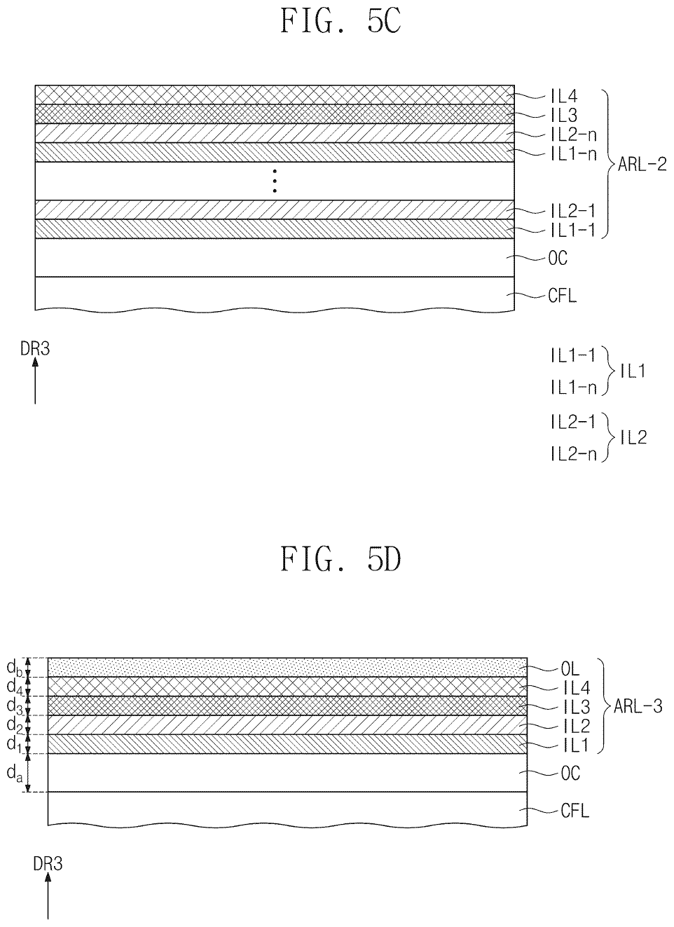

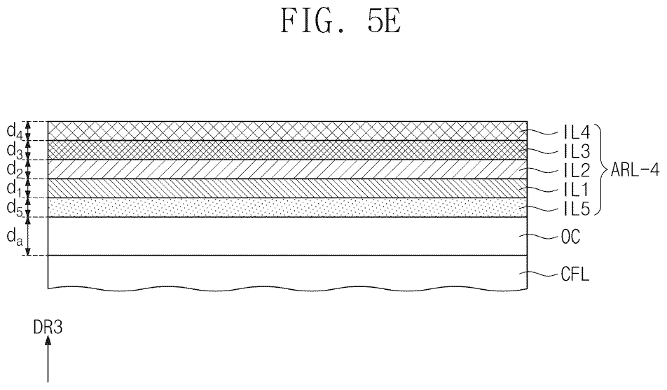

FIGS. 5A to 5E are cross-sectional views illustrating some elements of a display apparatus according to one or more embodiments of the present disclosure. Each of FIGS. 5A to 5E briefly illustrates a structure in which a color filter layer CFL, an overcoat layer OC, and anti-reflection layers ARL, ARL-1, ARL-2, ARL-3, and ARL-4 are stacked. Hereinafter, the anti-reflection layers ARL, ARL-1, ARL-2, ARL-3, and ARL-4 according to this present disclosure will be described in more detail with reference to FIGS. 5A to 5E.

Referring to FIGS. 4A and 5A together, the anti-reflection layer ARL is provided on the overcoat layer OC and includes a plurality of layers. The anti-reflection layer ARL includes a plurality of inorganic layers IL1, IL2, IL3, and IL4 provided on the overcoat layer OC.

The plurality of inorganic layers IL1, IL2, IL3, and IL4 include a first inorganic layer IL1, a second inorganic layer IL2, a third inorganic layer IL3, and a fourth inorganic layer IL4. The first inorganic layer IL1, the second inorganic layer IL2, the third inorganic layer IL3, and the fourth inorganic layer IL4 may be sequentially stacked in the thickness direction. The first inorganic layer IL1 may be provided on the overcoat layer OC. The second inorganic layer IL2 may be provided on the first inorganic layer IL1. The third inorganic layer IL3 may be provided on the second inorganic layer IL2. The fourth inorganic layer IL4 may be provided on the third inorganic layer IL3.

In one or more embodiments of the present disclosure, the first inorganic layer IL1 may be provided directly on the overcoat layer OC. The lower surface of the first inorganic layer IL1 may contact (e.g., come in contact with) the upper surface of the overcoat layer OC. The second inorganic layer IL2 may be provided directly on the first inorganic layer IL1. The lower surface of the second inorganic layer IL2 may contact (e.g., come in contact with) the upper surface of the first inorganic layer IL1. The third inorganic layer IL3 may be provided directly on the second inorganic layer IL2. The lower surface of the third inorganic layer IL3 may contact (e.g., come in contact with) the upper surface of the second inorganic layer IL2. The fourth inorganic layer IL4 may be provided directly on the third inorganic layer IL3. The lower surface of the fourth inorganic layer IL4 may contact (e.g., come in contact with) the upper surface of the third inorganic layer IL3.

Each of the first inorganic layer IL1 and the third inorganic layer IL3 may have a first refractive index. Each of the second inorganic layer IL2 and the fourth inorganic layer IL4 may have a second refractive index. In some embodiments, the first refractive index and the second refractive index may be defined at a wavelength of about 550 nm. At a wavelength of about 550 nm, the first refractive index may be about 1.80 to about 2.00. At a wavelength of about 550 nm, the second refractive index may be about 1.40 to about 1.50.

Each of the first to fourth inorganic layers IL1, IL2, IL3, and IL4 may include (e.g., contain) an inorganic material. The first inorganic layer IL1 and the second inorganic layer IL2 may have different refractive indices as they include (e.g., contain) different materials. In some embodiments, the third inorganic layer IL3 and the fourth inorganic layer IL4 may have different refractive indices as they include (e.g., contain) different materials. In one or more embodiments of the present disclosure, each of the first inorganic layer IL1 and the third inorganic layer IL3 may include (e.g., contain) silicon nitride (SiNₓ, x is an integer of 1 or more). Each of the second inorganic layer IL2 and the fourth inorganic layer IL4 may include (e.g., contain) silicon oxide (SiOₓ, x is an integer of 1 or more). For example, each of the first inorganic layer IL1 and the third inorganic layer IL3 may be made of silicon nitride. Each of the second inorganic layer IL2 and the fourth inorganic layer IL4 may be made of silicon oxide. In one or more embodiments of the present disclosure, the first to fourth inorganic layers IL1, IL2, IL3, and IL4 may be formed in a substantially continuous process in a same chamber. The first inorganic layer IL1 and the third inorganic layer IL3 may be film-formed by utilizing a same type or kind of gas, and the second inorganic layer IL2 and the fourth inorganic layer IL4 may be film-formed by utilizing a same type or kind of gas.

A thickness d₁ of the first inorganic layer IL1 may be about 10 nm to about 30 nm. A thickness d₂ of the second inorganic layer IL2 may be about 10 nm to about 30 nm. A thickness d₃ of the third inorganic layer IL3 may be greater than those of the first inorganic layer IL1, the second inorganic layer IL2, and the fourth inorganic layer IL4. The thickness d₃ of the third inorganic layer IL3 may be about 100 nm to about 150 nm. A thickness d₄ of the fourth inorganic layer IL4 may be about 10 nm to about 30 nm.

The anti-reflection layer ARL may have a low reflectance. The reflectance of the upper surface of the anti-reflection layer ARL may be about 2% or less. For example, the reflectance of the upper surface of the anti-reflection layer ARL may be about 0% to about 1%. In some embodiments, in the anti-reflection layer ARL illustrated in FIG. 5A, the upper surface of the anti-reflection layer ARL may be defined by the upper surface of the fourth inorganic layer IL4 provided at the uppermost portion of the plurality of inorganic layers IL1, IL2, IL3, and IL4.

While the anti-reflection layer ARL includes the plurality of inorganic layers IL1, IL2, IL3, and IL4, each of the first to fourth inorganic layers IL1, IL2, IL3, and IL4 included in the anti-reflection layer ARL has a refractive index of the described range and has a sequentially stacked structure and, therefore, the anti-reflection layer ARL may effectively prevent or reduce external light from being reflected from the surface of the display apparatus DD through destructive interference.

The overcoat layer OC configured to provide a base surface, on which the anti-reflection layer ARL is provided, may have a greater thickness than each layer included in the anti-reflection layer ARL. In one or more embodiments of the present disclosure, a thickness da of the overcoat layer OC may be about 3 μm to about 10 μm. In some embodiments, the overcoat layer OC may have a lower refractive index than the plurality of inorganic layers IL1, IL2, IL3, and IL4 included in the anti-reflection layer ARL. The overcoat layer OC may have a refractive index of about 1.45 to about 1.53.

In one or more embodiments of the present disclosure, at least one of the plurality of inorganic layers IL1, IL2, IL3, and/or IL4 may be hydrogenated. At least one of the first to fourth inorganic layers IL1, IL2, IL3, and/or IL4 may be hydrogenated. For example, each of the first inorganic layer IL1 and the second inorganic layer IL2 may be hydrogenated. In some embodiments, all of the first to fourth inorganic layers IL1, IL2, IL3, and IL3 may be hydrogenated. At least one of the plurality of inorganic layers IL1, IL2, IL3, and/or IL4 may be doped with hydrogen inside a film.

At least one of the plurality of inorganic layers IL1, IL2, IL3, and/or IL4 may be hydrogenated by hydrogen (H₂) plasma. At least one of the plurality of inorganic layers IL1, IL2, IL3, and/or IL4 may be formed by plasma-treating a silicon nitride (SiNₓ) film or a silicon oxide (SiOₓ) film by utilizing hydrogen (H₂). In some embodiments, the inorganic layer may be hydrogenated by adding hydrogen (H₂) to a reaction gas for forming the inorganic layer. For example, when the first inorganic layer IL1 is hydrogenated, after the silicon nitride (SiNₓ) film is formed, the first inorganic layer IL1 may be hydrogenated through hydrogen (H₂) plasma treatment of the surface of the silicon nitride (SiNₓ) film. In some embodiments, the first inorganic layer IL1 may be hydrogenated by adding a hydrogen (H₂) gas to a reaction gas for forming the first inorganic layer IL1. The hydrogenated inorganic layer may have a high film density. As the inorganic layer is treated with hydrogen, free radicals or outermost electrons present on the surface of the inorganic layer combine with hydrogen of the hydrogen plasma, thus improving the inner density of the film. Accordingly, the hydrogen-treated inorganic layer may exhibit excellent or suitable mechanical properties and durability.

In some embodiments, the hydrogenated inorganic layer selected from among the plurality of inorganic layers IL1, IL2, IL3, and IL4 may include a first layer including (e.g., containing) hydrogen and a second layer including (e.g., containing) little or no hydrogen. In the hydrogenated inorganic layer, the first layer may correspond to the upper portion of the inorganic layer in the thickness direction, and the second layer may correspond to the lower portion of the inorganic layer in the thickness direction. For example, each of the plurality of inorganic layers IL1, IL2, IL3, and IL4 may include one surface adjacent to the display panel and the other surface opposite to the one surface and spaced and/or apart from the display panel, and in the hydrogenated inorganic layer selected from among the plurality of inorganic layers IL1, IL2, IL3, and IL4, the first layer may be adjacent to the other surface and the second layer may be adjacent to the one surface. The first layer and the second layer may have an integrated shape. Without being limited thereto, however, in the hydrogenated inorganic layer selected from among the plurality of inorganic layers IL1, IL2, IL3, and IL4, hydrogen may be uniformly present inside the thin film.

In one or more embodiments of the present disclosure, the first inorganic layer IL1 may include (e.g., contain) hydrogenated silicon nitride (SiNₓ:H). The first inorganic layer IL1 may be formed of hydrogenated silicon nitride (SiNₓ:H). The second inorganic layer IL2 may include (e.g., contain) hydrogenated silicon oxide (SiOₓ:H). The second inorganic layer IL2 may be formed of hydrogenated silicon oxide (SiOₓ:H). The third inorganic layer IL3 may include (e.g., contain) hydrogenated silicon nitride (SiNₓ:H). The third inorganic layer IL3 may be formed of hydrogenated silicon nitride (SiNₓ:H). The fourth inorganic layer IL4 may include (e.g., contain) hydrogenated silicon oxide (SiOₓ:H). The fourth inorganic layer IL4 may be formed of hydrogenated silicon oxide (SiOₓ:H).

Referring to FIG. 5B, unlike the anti-reflection layer ARL according to one or more embodiments of the present disclosure illustrated in FIG. 5A, in the anti-reflection layer ARL-1 according to one or more embodiments of the present disclosure, each of a first inorganic layer IL1 and a second inorganic layer IL2 may be provided in plurality. Each of the first inorganic layer IL1 and the second inorganic layer IL2 may be provided as a plurality of layers. As illustrated in FIG. 5B, the first inorganic layer IL1 may include a (1-1)-th inorganic layer IL1-1 and a (1-2)-th inorganic layer IL1-2. The second inorganic layer IL2 may include a (2-1)-th inorganic layer IL2-1 and a (2-2)-th inorganic layer IL2-2.

The first inorganic layer IL1 and the second inorganic layer IL2 each provided as a plurality of layers may be alternately provided. For example, any two layers of the plurality of first inorganic layers IL1 may not be continuously stacked, and any one of the second inorganic layers IL2 may be provided between the plurality of first inorganic layers IL1. In some embodiments, any two layers of the plurality of second inorganic layers IL2 may not be continuously stacked, and any one of the first inorganic layers IL1 may be provided between the plurality of second inorganic layers IL2.

As illustrated in FIG. 5B, the (2-1)-th inorganic layer IL2-1 may be provided on the (1-1)-th inorganic layer IL1-1, the (1-2)-th inorganic layer IL1-2 may be provided on the (2-1)-th inorganic layer IL2-1, and the (2-2)-th inorganic layer IL2-2 may be provided on the (1-2)-th inorganic layer IL1-2. The (1-1)-th inorganic layer IL1-1, the (2-1)-th inorganic layer IL2-1, the (1-2)-th inorganic layer IL1-2, and the (2-2)-th inorganic layer IL2-2 may have a continuously stacked structure. For example, the (2-1)-th inorganic layer IL2-1 may be provided directly on the (1-1)-th inorganic layer IL1-1, the (1-2)-th inorganic layer IL1-2 may be provided directly on the (2-1)-th inorganic layer IL2-1, and the (2-2)-th inorganic layer IL2-2 may be provided directly on the (1-2)-th inorganic layer IL1-2. The lowermost layer among the plurality of first inorganic layers IL1 and the plurality of second inorganic layers IL2 may be provided directly on the overcoat layer OC. As illustrated in FIG. 5B, the (1-1)-th inorganic layer IL1-1 among the plurality of first inorganic layers IL1 may be provided on the overcoat layer OC, and the (2-1)-th inorganic layer IL2-1, the (1-2)-th inorganic layer IL1-2, and the (2-2)-th inorganic layer IL2-2 may be sequentially stacked on the (1-1)-th inorganic layer IL1-1. In some embodiments, FIG. 5B illustrates by example that the (1-1)-th inorganic layer IL1-1 included in the first inorganic layer IL1 among the plurality of first inorganic layers IL1 and the plurality of second inorganic layers IL2 is provided directly on the overcoat layer OC, but without being limited thereto, a layer included in the second inorganic layer IL2 may be provided directly on the overcoat layer OC. For example, the (2-1)-th inorganic layer IL2-1 may be provided directly on the overcoat layer OC, and the (1-1)-th inorganic layer IL1-1, the (2-2)-th inorganic layer IL2-2, and the (1-2)-th inorganic layer IL1-2 may be sequentially stacked on the (2-1)-th inorganic layer IL2-1.

The first inorganic layer IL1 has a first refractive index, and the second inorganic layer IL2 has a second refractive index smaller than the first refractive index. In some embodiments, the first refractive index and the second refractive index may be defined at a wavelength of about 550 nm. At a wavelength of about 550 nm, the first refractive index may be about 1.80 to about 2.00. At a wavelength of about 550 nm, the second refractive index may be about 1.40 to about 1.50. For example, the first refractive index may be about 1.86, and the second refractive index may be about 1.48. Each of the first inorganic layers IL1 provided as a plurality of layers may have a first refractive index, and each of the second inorganic layers IL2 provided as a plurality of layers may have a second refractive index. For example, each of the (1-1)-th inorganic layer IL1-1 and the (1-2)-th inorganic layer IL1-2 illustrated in FIG. 5B may have the first refractive index, and each of the (2-1)-th inorganic layer IL2-1 and the (2-2)-th inorganic layer IL2-2 may have the second refractive index.

Each of the plurality of first inorganic layers IL1 may include (e.g., contain) silicon nitride. For example, each of the (1-1)-th inorganic layer IL1-1 and the (1-2)-th inorganic layer IL1-2 may include (e.g., contain) silicon nitride. Each of the plurality of second inorganic layers IL2 may include (e.g., contain) silicon oxide. For example, each of the (2-1)-th inorganic layer IL2-1 and the (2-2)-th inorganic layer IL2-2 may include (e.g., contain) silicon oxide. The plurality of first inorganic layers IL1 and the plurality of second inorganic layers IL2 may include (e.g., contain) different materials and, therefore, have different refractive indices as described herein. Each of the plurality of first inorganic layers IL1 may include (e.g., be composed of) silicon nitride. For example, each of the (1-1)-th inorganic layer IL1-1 and the (1-2)-th inorganic layer IL1-2 may include (e.g., be composed of) silicon nitride. Each of the plurality of second inorganic layers IL2 may include (e.g., be composed of) silicon oxide. For example, each of the (2-1)-th inorganic layer IL2-1 and the (2-2)-th inorganic layer IL2-2 may include (e.g., be composed of) silicon oxide. The plurality of first inorganic layers IL1 and the plurality of second inorganic layers IL2 may be formed in a substantially continuous process in a same chamber. The first inorganic layer IL1 and the second inorganic layer IL2 may be formed by utilizing different reaction gases. In some embodiments, each of the plurality of first inorganic layers IL1 may be film-formed by utilizing a same type or kind of gas. Each of the plurality of second inorganic layers IL2 may be film-formed by utilizing a same type or kind of gas.

In the first inorganic layer IL1 and the second inorganic layer IL2 each provided as a plurality of layers, each of the plurality of first inorganic layers IL1 and the plurality of second inorganic layers IL2 may have a thickness of about 10 nm to about 30 nm. As illustrated in FIG. 5B, the anti-reflection layer ARL may include a (1-1)-th inorganic layer IL1-1, a (2-1)-th inorganic layer IL2-1, a (1-2)-th inorganic layer IL1-2, and a (2-2)-th inorganic layer IL2-2 which are sequentially stacked, and the thickness of each of the (1-1)-th inorganic layer IL1-1, the (2-1)-th inorganic layer IL2-1, the (1-2)-th inorganic layer the IL1-2 and the (2-2)-th inorganic layer IL2-2 may be about 10 nm to about 30 nm.

The anti-reflection layer ARL-1 may have a low reflectance. The reflectance of the upper surface of the anti-reflection layer ARL-1 may be about 2% or less. For example, the reflectance of the upper surface of the anti-reflection layer ARL-1 may be about 1% or less. In some embodiments, in the anti-reflection layer ARL illustrated in FIG. 5B, the upper surface of the anti-reflection layer ARL may be defined by the upper surface of the fourth inorganic layer IL4 provided at the uppermost portion of the plurality of inorganic layers IL1, IL2, IL3, and IL4. While the anti-reflection layer ARL-1 includes the plurality of inorganic layers IL1, IL2, IL3, and IL4, each of the plurality of first inorganic layers IL1 and the plurality of second inorganic layers IL2 included in the anti-reflection layer ARL-1 has a refractive index of the described range and has a structure in which they are alternately provided and, therefore, the anti-reflection layer ARL-1 may effectively prevent or reduce external light from being reflected from the surface of the display apparatus DD through destructive interference.

The overcoat layer OC configured to provide a base surface on which the anti-reflection layer ARL-1 is provided may have a greater thickness than each layer included in the anti-reflection layer ARL-1. In one or more embodiments of the present disclosure, the overcoat layer OC may have a thickness of about 3 μm to about 10 μm. In some embodiments, the overcoat layer OC may have a lower refractive index than the plurality of inorganic layers IL1, IL2, IL3, and IL4 included in the anti-reflection layer ARL-1. The overcoat layer OC may have a refractive index of about 1.45 to about 1.53.

Referring to FIG. 5C, unlike the anti-reflection layers ARL and ARL-1 according to one or more embodiments of the present disclosure illustrated in FIGS. 5A and 5B, the anti-reflection layer ARL-2 according to one or more embodiments of the present disclosure may include n first inorganic layers IL1-1 to IL-1n and n second inorganic layers IL2-1 to IL2-n. In some embodiments, n may be an integer of 3 to 10. For example, the anti-reflection layer ARL-2 according to one or more embodiments of the present disclosure may include a repeating unit structure including any one of the plurality of first inorganic layers IL1 and any one of the plurality of second inorganic layers IL2 and have a structure of the inorganic layers IL1 and IL2, in which 3 to 10 repeating unit structures are sequentially stacked. The number of repeating unit structures and the thickness of each repeating unit structure may be selected within a range to perform the anti-reflection function of the anti-reflection layer ARL-2 and the aforementioned thickness range.

The description of the first inorganic layer IL1 described herein with reference to FIG. 5A may be applied to each of the n first inorganic layers IL1-1 to IL-1n included in the anti-reflection layer ARL-2. The description of the second inorganic layer IL2 described herein with reference to FIG. 5A may be applied to each of the n second inorganic layers IL2-1 to IL-2n included in the anti-reflection layer ARL-2.

In the anti-reflection layer included in the display apparatus according to one or more embodiments of the present disclosure, the first inorganic layer IL1 and the second inorganic layer IL2 each include (e.g., contain) different materials and thus have different refractive indices. In the anti-reflection layer according to one or more embodiments of the present disclosure, because the alternately stacked structure of the first inorganic layer IL1 and the second inorganic layer IL2 may be formed to have different detailed compositions by controlling the type or kind and partial pressure of a raw material gas in a same chamber, it is possible to easily change the refractive index of each of the first inorganic layer IL1 and the second inorganic layer IL2 included in the plurality of inorganic layers by simply changing a process condition and, therefore, it is also possible to easily form the structure of the anti-reflection layer having refractive index and reflection characteristics within a range that matches those of other elements included in the display apparatus DD.

In some embodiments, because the anti-reflection layer ARL-2 according to one or more embodiments of the present disclosure includes a structure in which the plurality of first inorganic layers IL1 including (e.g., containing) silicon nitride and the plurality of second inorganic layers IL2 including (e.g., containing) silicon oxide are alternately stacked, the property of blocking moisture, oxygen, and/or the like from entering the display apparatus from the outside may be improved, thus making it possible to form the structure of the anti-reflection layer having a high capping property.

Referring to FIG. 5D, unlike the anti-reflection layer ARL according to one or more embodiments of the present disclosure illustrated in FIG. 5A, the anti-reflection layer ARL-3 according to one or more embodiments of the present disclosure may further include a low refraction layer OL provided on a plurality of inorganic layers IL1, IL2, IL3, and IL4. The low refraction layer OL may have a lower refractive index than (e.g., that of each of) the plurality of inorganic layers IL1, IL2, IL3, and IL4.

A separate layer may be omitted (e.g., not be provided) on the low refraction layer OL. For example, the low refraction layer OL may be the outermost layer provided at the uppermost portion of the anti-reflection layer ARL-3. The upper surface of the low refraction layer OL may define the outermost surface of the anti-reflection layer ARL-3. The low refraction layer OL may be the outermost layer of the display apparatus DD (see FIG. 2) including the anti-reflection layer ARL-3.

In the anti-reflection layer ARL-3 according to one or more embodiments of the present disclosure, the plurality of inorganic layers IL1 and IL2 may have a refractive index of about 1.4 or more, and the low refraction layer OL may have a refractive index of about 1.25 or more to less than about 1.40. For example, the low refraction layer OL may have a refractive index of about 1.25 to about 1.30. A thickness d_{b} of the low refraction layer OL may be about 60 nm to about 110 nm.

The anti-reflection layer ARL-3 according to one or more embodiments of the present disclosure includes a plurality of inorganic layers IL1, IL2, IL3, and IL4, each of the plurality of inorganic layers IL1, IL2, IL3, and IL4 has a refractive index within the aforementioned ranges, and the anti-reflection layer ARL-3 has a structure in which the plurality of first inorganic layers IL1 and the plurality of second inorganic layers IL2 are alternately provided. In some embodiments, the low refraction layer OL having a low refractive index is provided at the uppermost portion of the anti-reflection layer ARL-3 and, therefore, it is possible to effectively prevent or reduce external light from being reflected on the surface of the anti-reflection layer ARL-3 through destructive interference.

Referring to FIG. 5E, unlike the anti-reflection layer ARL according to one or more embodiments of the present disclosure illustrated in FIG. 5A, the anti-reflection layer ARL-4 according to one or more embodiments of the present disclosure may further include a fifth inorganic layer IL5 provided below (or on or under) a plurality of inorganic layers IL1, IL2, IL3, and IL4.

In one or more embodiments of the present disclosure, the fifth inorganic layer IL5 may be provided the first inorganic layer IL1. The fifth inorganic layer IL5 may be provided between the first inorganic layer IL1 and the overcoat layer OC. The fifth inorganic layer IL5, the first inorganic layer IL1, the second inorganic layer IL2, the third inorganic layer IL3, and the fourth inorganic layer IL4 may be sequentially stacked in the thickness direction. In one or more embodiments of the present disclosure, the fifth inorganic layer IL5 may be provided directly on the overcoat layer OC. The first inorganic layer IL1 may be provided directly on the fifth inorganic layer IL5. The second inorganic layer IL2 may be provided directly on the first inorganic layer IL1. The third inorganic layer IL3 may be provided directly on the second inorganic layer IL2. The fourth inorganic layer IL4 may be provided directly on the third inorganic layer IL3.

The fifth inorganic layer IL5 may have the aforementioned second refractive index. At a wavelength of about 550 nm, the refractive index of the fifth inorganic layer IL5 may be about 1.40 to about 1.50.

In one or more embodiments of the present disclosure, the fifth inorganic layer IL5 may include (e.g., contain) silicon oxide (SiOₓ). For example, the fifth inorganic layer IL5 may include (e.g., be composed of) silicon oxide (SiOₓ). In one or more embodiments of the present disclosure, the first to fifth inorganic layers IL1, IL2, IL3, IL4, and IL5 may be formed in a substantially continuous process in a same chamber. The fifth inorganic layer IL5, the first inorganic layer IL1, and the third inorganic layer IL3 may be film-formed by utilizing a same type or kind of gas, and the second inorganic layer IL2 and the fourth inorganic layer IL4 may be film-formed by utilizing a same type or kind of gas. A thickness d₅ of the fifth inorganic layer IL5 may be about 30 nm to about 1200 nm.

The anti-reflection layer ARL-4 according to one or more embodiments of the present disclosure includes a plurality of inorganic layers IL1, IL2, IL3, and IL4, and a fifth inorganic layer IL5 provided the plurality of inorganic layers, and each of the plurality of inorganic layers IL1, IL2, IL3, and IL4 and the fifth inorganic layer IL5 has a refractive index within the aforementioned ranges and, therefore, it is possible to effectively prevent or reduce external light from being reflected on the surface of the anti-reflection layer ARL-3 through destructive interference.

In the display apparatus according to one or more embodiments of the present disclosure, the anti-reflection layer provided on the display panel is not in the form of a film, but is a layer formed directly on the upper surface of the overcoat layer through deposition and/or the like, and the anti-reflection layer includes first to fourth inorganic layers IL1, IL2, IL3, and IL4 having different refractive indices. Each of the first inorganic layer IL1 and the third inorganic layer IL3 included in the anti-reflection layers ARL, ARL-1, ARL-2, and ARL-3 includes (e.g., contains) silicon nitride and has a first refractive index, and each of the second inorganic layer IL2 and the fourth inorganic layer IL4 includes (e.g., contains) silicon oxide and has a second refractive index smaller than the first refractive index. As the display apparatus according to one or more embodiments of the present disclosure includes a structure in which the plurality of inorganic layers IL1, IL2, IL3, and IL4 are sequentially stacked, it is possible to form the structure of the anti-reflection layer having low reflectance and high capping characteristics through a simple process, thus making it possible to improve the visibility and durability of the display apparatus.

For example, in the anti-reflection layer included in the display apparatus according to one or more embodiments of the present disclosure, the first inorganic layer IL1 and the third inorganic layer IL3 included in the plurality of inorganic layers are formed of silicon nitride, the second inorganic layer IL2 and the fourth inorganic layer IL4 are formed of silicon oxide, and by varying a reaction gas in a same chamber, it is possible to form a structure in which the plurality of inorganic layers IL1, IL2, IL3, and IL4 are sequentially stacked, thus making it possible to simplify a process of forming the anti-reflection layer.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display apparatus and any other relevant devices or components according to embodiments of the present disclosure described herein may be implemented utilizing any suitable hardware, firmware (e.g., an application-specific integrated circuit), software, or a combination of software, firmware, and hardware. For example, the various components of the display apparatus may be formed on one integrated circuit (IC) chip or on separate IC chips. Further, the various components of the display apparatus may be implemented on a flexible printed circuit film, a tape carrier package (TCP), a printed circuit board (PCB), or formed on one substrate. Further, the various components of the display apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In present disclosure, “not including a or any ‘component’” “excluding a or any ‘component’”, “‘component’-free”, and/or the like refers to that the “component” not being added, selected or utilized as a component in the composition or device, but the “component” of less than a suitable amount may still be included due to other impurities and/or external factors.

Hereinafter, the display apparatus including an anti-reflection layer according to one or more embodiments of the present disclosure will be described in more detail with reference to embodiments and a comparative embodiment. The embodiments described are only examples for helping understanding of this present disclosure, and the scope of this present disclosure is not limited thereto.

### EXAMPLES

### Example 1

A color filter layer having the structure described for FIG. 4A was formed on a glass substrate, and an anti-reflection layer having the structure described for FIG. 5A was formed on the color filter layer. A first inorganic layer having a refractive index of about 1.86 was formed with a thickness of about 15 nm on the color filter layer, and a second inorganic layer having a refractive index of about 1.48 was formed with a thickness of about 15 nm on the first inorganic layer. Hereafter, a third inorganic layer having a refractive index of about 1.86 was formed with a thickness of about 125 nm on the second inorganic layer, and a fourth inorganic layer having a refractive index of about 1.48 was formed with a thickness of about 20 nm on the third inorganic layer. Then, a low refraction layer having a refractive index of about 1.30 was formed with a thickness of about 95 nm on the fourth inorganic layer. The first inorganic layer and the third inorganic layer correspond to thin films including (e.g., containing) silicon nitride, and the second inorganic layer and the fourth inorganic layer correspond to thin films including (e.g., containing) silicon oxide.

### Example 2

Example 2 was prepared in substantially the same manner as in Example 1 except that the first inorganic layer was stacked with a thickness of about 20 nm and the second inorganic layer was stacked with a thickness of about 20 nm.

### Comparative Example 1

A display apparatus of Comparative Example 1 was prepared in substantially the same manner as in Example 1 except that the first and second inorganic layers of Example 1 were replaced with a single-layered inorganic layer including (e.g., containing) silicon oxynitride (SiON). For example, in Comparative Example 1, the first inorganic layer and the second inorganic layer are omitted from the anti-reflection layer corresponding to FIG. 5A, and Comparative Example 1 has a structure in which a silicon oxynitride film having a refractive index of about 1.6 is stacked with a thickness of about 60 nm.

Table 1 shows the measured values of reflectance of the display apparatuses of Examples 1 and 2 and Comparative Example 1. SCI, SCE, and SC of the display apparatuses prepared according to Examples 1 and 2 and Comparative Example 1 were measured and are shown in Table 1. Here, SCI is a total reflection value, SCE is a diffused reflection value, and SC is a specular reflection value. In Table 1, the SCI, SCE, and SC correspond to the values of reflectance measured at a wavelength of about 550 nm.

TABLE 1

| Division | Example 1 | Example 2 | Comparative Example 1 |
|---|---|---|---|
| SCI | 0.4 | 0.4 | 0.6 |
| SCE | 0.1 | 0.1 | 0.1 |
| SC | 0.3 | 0.3 | 0.6 |

Referring to Table 1 herein, it may be seen that the display apparatuses of Examples 1 and 2 show SCI, SCE, and SC values similar to those of Comparative Example 1. When Example 1 and Example 2 are compared with Comparative Example 1, it can be seen that Examples 1 and 2 exhibit reflectance characteristics in which the reflectance levels of the embodiments are lower than or similar to that of Comparative Example 1 including (e.g., containing) silicon oxynitride.

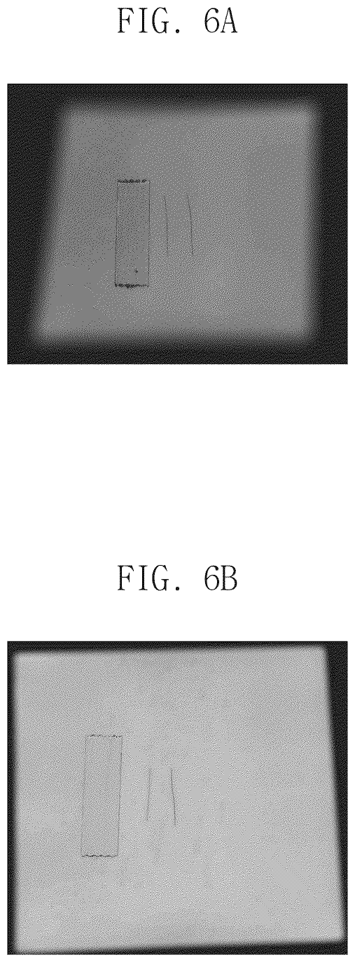

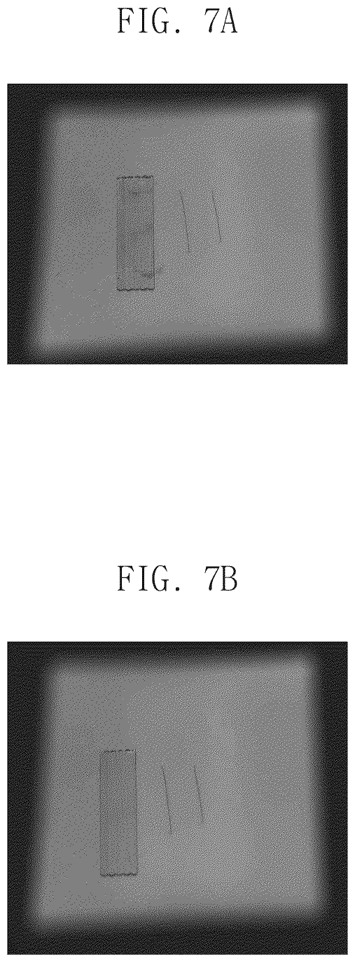

FIGS. 6A, 6B, 7A, and 7B show the measurement results of wet high temperature storage (WHTS) tests for Examples 1 and 2 and Comparative Example 1. The WHTS test is a high-temperature and high-humidity storage test, which refers to a test in which a measurement object is stored in an oven at a temperature of about 85° C. and at a relative humidity of about 85%. FIGS. 6A, 6B, 7A, and 7B show the results after leaving substrate samples of Examples 1 and 2 and Comparative Example in a high-temperature and high-humidity atmosphere at a temperature of about 85° C. and at a relative humidity of about 85% for 24 hours. FIGS. 6A and 6B show WHTS test results for Comparative Example 1, and FIGS. 7A and 7B show WHTS test results for Example 1. FIG. 6A is an image of a substrate sample of Comparative Example 1 taken before the WHTS test, and FIG. 6B is an image of a substrate sample of Comparative Example 1 taken 24 hours after the WHTS test. FIG. 7A is an image of a substrate sample of Example 1 taken before the WHTS test, and FIG. 7B is an image of a substrate sample of Example 1 taken 24 hours after the WHTS test.

Referring to FIGS. 6A and 6B, it may be seen that, after the WHTS test, a stain occurred in Comparative Example 1, when compared to Example 1. In Comparative Example 1, when compared to Example 1, the first inorganic layer and the second inorganic layer were replaced with the inorganic layer including (e.g., containing) silicon oxynitride (SiON). Referring to Table 1 and FIGS. 6A and 6B together, it may be seen that Comparative Example 1 into which an anti-reflection layer including (e.g., containing) silicon oxynitride (SiON) was introduced exhibited a reflectance equivalent to that of Example 1, but the high-temperature and high-humidity stability of Comparative Example 1 was significantly lower than that of Example 1. Silicon oxynitride (SiON) is gradually oxidized and changed into silicon oxide (SiOₓ) in a high-temperature and high-humidity environment. Accordingly, the external light reflectance of the anti-reflection layer including (e.g., containing) silicon oxynitride (SiON) may change, thereby causing a stain. Therefore, when Comparative Example 1 is applied to the display apparatus, a quality defect may occur in a reliability evaluation.

On the other hand, referring to FIGS. 7A and 7B, in Example 1, when compared to Comparative Example 1, it may be seen that a stain does not occur after the WHTS test. In Example 1, when compared to Comparative Example 1, it can be seen that oxidation can be suppressed or reduced in a high-temperature and high-humidity environment and accordingly a change in composition inside the thin film is reduced in a high-temperature and high-humidity environment, thus making it possible to maintain the effect of preventing or reducing reflection of external light. Referring to Table 1 and FIGS. 7A and 7B together, it may be seen that Example 1 may exhibit the effect of improving resistance to a high temperature and high humidity condition while maintaining a reflectance similar to that of Comparative Example 1. Accordingly, when the anti-reflection layer according to one or more embodiments of the present disclosure is applied to the display apparatus, it is possible to provide a user with the display apparatus having improved reliability while exhibiting the effect of excellently reducing the reflection of external light.

In some embodiments, a change in the elemental composition of the inorganic layer included in the substrate sample may be checked through an X-ray photoelectron spectroscopy (XPS) or by an Fourier-transform infrared (FT-IR) spectrometer. For example, in the inorganic layer included in Comparative Example 1, the silicon oxynitride (SiON) film may be oxidized after the WHTS test, so that the content (e.g., amount) of oxygen (O) in the thin film may increase and the content (e.g., amount) of nitrogen (N) therein may decrease. In some embodiments, in a FT-IR spectrum of Comparative Example 1 measured after the WHTS test, a peak of SiON may be changed to a peak of SiOₓ. For example, when compared to the FT-IR spectrum of Comparative Example 1 measured before the WHTS test, the FT-IR spectrum of Comparative Example 1 measured after the WHTS test may exhibit a tendency in which a peak of Si—O rises in an oxygen bonding state and a peak of Si—N falls in a nitrogen bonding state. In contrast, the inorganic layer included in the embodiments may have no change in elemental composition even after the WTHS test, and through this, it can be predicted that no oxidation reaction occurs even in a high-temperature and high-humidity environment.

Depending on the type or kind of material utilized for the inorganic layer of the anti-reflection layer, reflectance and high-temperature and high-humidity reliability may vary. According to this present disclosure, by utilizing silicon nitride (SiNₓ) and silicon oxide (SiOₓ) for the inorganic layer applied to the anti-reflection layer, it is possible to provide the display apparatus that exhibits low reflectance characteristics and improved high-temperature and high-humidity reliability.

Comparably, silicon oxynitride (SiON) having high transmittance has been applied as a type or kind of inorganic layer material of the anti-reflection layer. In this case, a silicon oxynitride (SiON) thin film may be applied to the anti-reflection layer to contribute to low reflectance characteristics, but the internal composition thereof may change in a high-temperature and high-humidity environment and the refractive index thereof may change. Accordingly, there may be a weakness such as the occurrence of a stain. According to this present disclosure, by including silicon nitride (SiNₓ) and silicon oxide (SiOₓ) as the inorganic layer material of the anti-reflection layer, when compared to the anti-reflection layer into which silicon oxynitride (SiON) is introduced, the anti-reflection layer according to this present disclosure exhibits the same level of reflectance reduction effects and may also exhibit improved high-temperature and high-humidity resistance compared to an existing inorganic layer, thereby making it possible to improve the reliability of the display apparatus. The display apparatus according to one or more embodiments of the present disclosure may have a lightweight and slim structure. As a method for protecting the display apparatus, an encapsulation method utilizing metal or glass may be applied. However, this method has a limitation in that the process is complicated and expensive. In the display apparatus according to one or more embodiments of the present disclosure, because the anti-reflection layer having high resistance to high temperature and high humidity is provided at the uppermost portion of the display apparatus, reliability is improved, and metal or glass applied for sealing the upper portion thereof may be omitted (e.g., not be provided), thereby having an advantage in which a thin and lightweight display apparatus may be implemented.

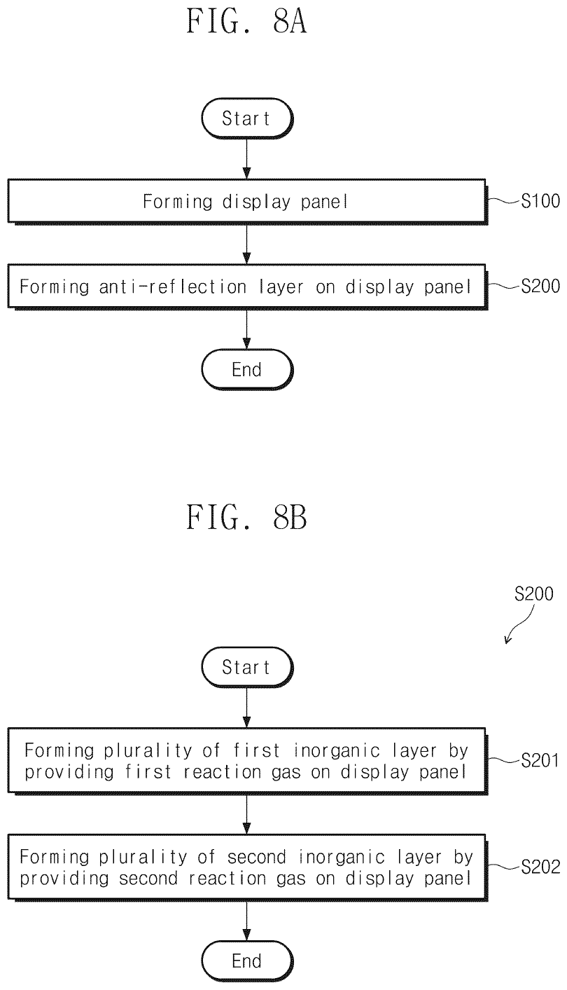

FIG. 8A is a flowchart showing a method of manufacturing a display apparatus according to one or more embodiments of the present disclosure. FIG. 8B is a flowchart that subdivides the step of forming an anti-reflection layer according to one or more embodiments of the present disclosure.

Referring to FIG. 8A, the method of manufacturing the display apparatus according to one or more embodiments of the present disclosure includes forming a display panel (S100) and forming an anti-reflection layer on the display panel (S200).

Referring to FIG. 8B, the forming of the anti-reflection layer (S200) according to one or more embodiments of the present disclosure includes forming a first inorganic layer by providing a first reaction gas on the display panel (S201) and forming a second inorganic layer by providing a second reaction gas on the display panel (S202).

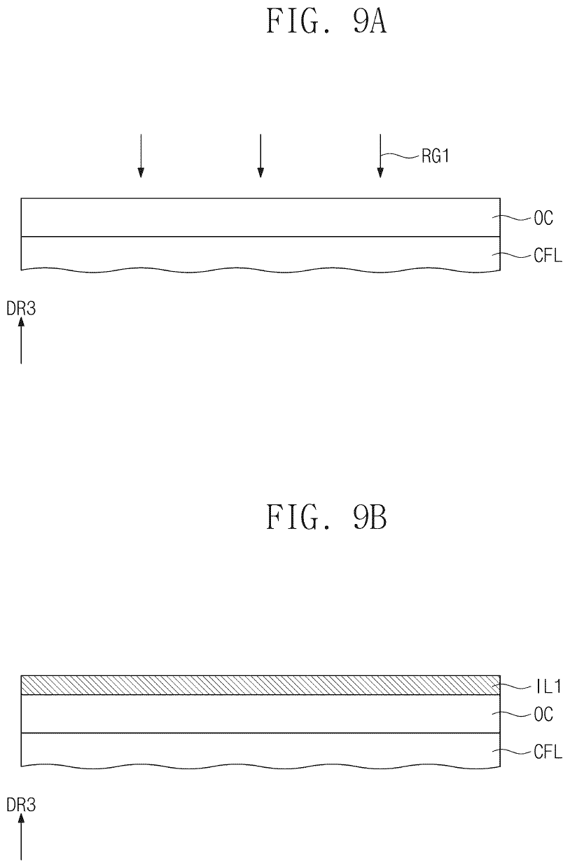

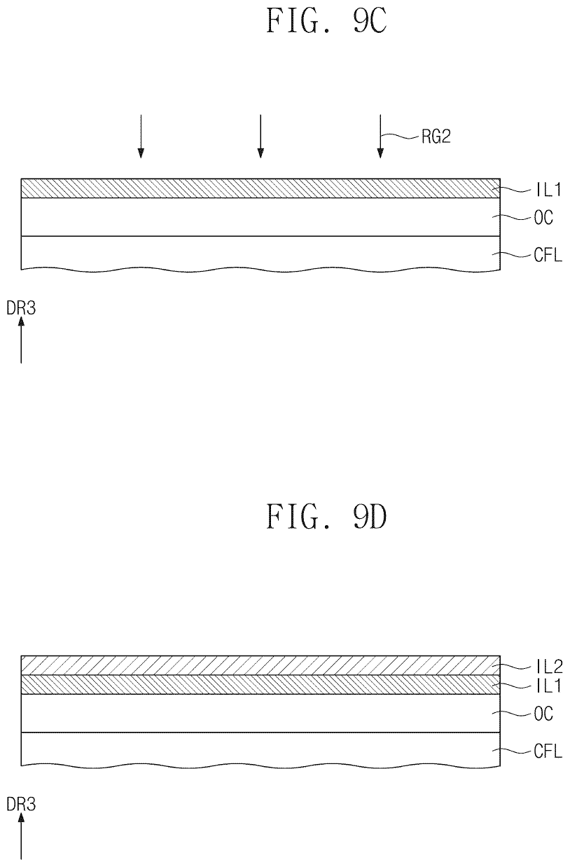

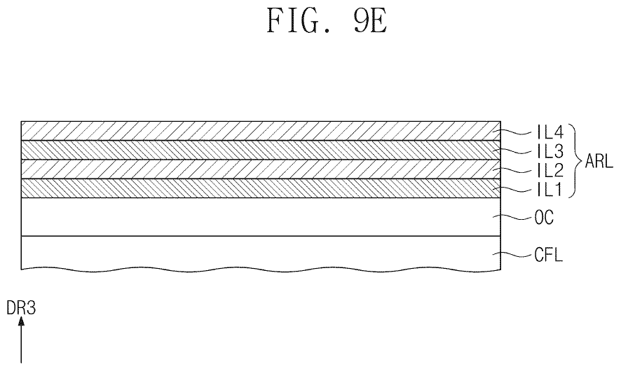

FIGS. 9A to 9E are cross-sectional views illustrating some steps of the method of manufacturing the display apparatus according to one or more embodiments of the present disclosure. FIGS. 9A to 9E sequentially illustrate the steps of forming an anti-reflection layer in the method of manufacturing the display apparatus according to one or more embodiments of the present disclosure. Hereinafter, in describing the method of manufacturing the display apparatus according to one or more embodiments of the present disclosure with reference to FIGS. 9A to 9E, the same reference numerals are assigned to components identical to those described herein, and the detailed descriptions thereof are omitted.

Referring to FIGS. 9A and 9B, a first inorganic layer IL1 may be formed through chemical vapor deposition. In one or more embodiments of the present disclosure, the first inorganic layer IL1 may be formed through plasma enhanced chemical vapor deposition (PECVD). The first inorganic layer IL1 may be formed on the display panel. For example, through the forming of the display panel (S100), the base substrate BS, the circuit layer DP-CL, and the display element layer DP-ED may be sequentially formed, and the first inorganic layer IL1 may be formed on the display element layer DP-ED. In some embodiments, prior to the forming of the anti-reflection layer (S200), forming the light control layer CCL (see FIG. 4A), the color filter layer CFL (see FIG. 4A), and the overcoat layer OC (see FIG. 4A) on the display panel may be performed. As illustrated in FIG. 9A, the first inorganic layer IL1 may be deposited on the overcoat layer OC formed on the display panel.

Referring to FIG. 9A, the forming of the first inorganic layer may be performed by providing the first reaction gas on the display panel (S201). In some embodiments, the forming of the first inorganic layer (S201) may be performed in a deposition chamber. The forming of the first inorganic layer may include forming a silicon nitride (SiNₓ) film by providing a first reaction gas on the display panel. The first reaction gas RG1 may be provided on the overcoat layer OC. In one or more embodiments of the present disclosure, in order to form the first inorganic layer including (e.g., containing) silicon nitride (SiNₓ), the first reaction gas RG1 may include monosilane (SiH₄), nitrogen (N₂), and ammonia (NH₃). In this case, x corresponding to a composition ratio of silicon nitride (SiNₓ) may vary according to the ratio of each of monosilane (SiH₄), nitrogen (N₂), and ammonia (NH₃) to the first reaction gas RG1. The first reaction gas RG1 may be injected into a chamber and ionized to be in a plasma state. Hereafter, the components of the first reaction gas RG1 in a plasma state may chemically react with each other and be deposited on the overcoat layer OC to form the first inorganic layer IL1 including (e.g., containing) silicon nitride (SiNₓ) and having a set or predetermined thickness.

In some embodiments, after the forming of the first inorganic layer (S201), hydrogenating the first inorganic layer may be performed. For example, hydrogen may be doped into the first inorganic layer IL1 by providing hydrogen plasma on the first inorganic layer IL1. The amount of hydrogen doped into the first inorganic layer IL1 may be adjusted by changing the flow rate and air pressure of hydrogen (H₂) gas which is introduced into the chamber.

The hydrogen plasma may be doped into the first inorganic layer IL1 to increase density in the film. In the hydrogenating of the first inorganic layer IL1, by providing the hydrogen (H₂) plasma on the first inorganic layer IL1, it is possible to make silicon nitride (SiNₓ) included in the first inorganic layer IL1 react with the hydrogen plasma. For example, in the hydrogenating of the first inorganic layer IL1, by making hydrogen atoms doped into the silicon nitride thin film, it is possible to make the hydrogen atoms form new bonds with silicon atoms (Si) or nitrogen atoms (N) in the silicon nitride (SiNₓ). For example, the hydrogen plasma may react with silicon nitride (SiNₓ) included in the first inorganic layer IL1 to form a Si—H bond or a N—H bond. Silicon nitride (SiNₓ) included in the first inorganic layer IL1 may be changed into hydrogenated silicon nitride (SiNₓ:H) after the hydrogenating of the first inorganic layer IL1. Accordingly, the hydrogenated first inorganic layer IL1 may have a high film density and exhibit excellent or suitable durability and reliability characteristics when applied to a display apparatus.

However, the method of hydrogenating the first inorganic layer IL1 is not limited thereto, and the hydrogenation of the first inorganic layer IL1 may be achieved by adding hydrogen (H₂) in the first reaction gas RG1 utilized to form the first inorganic layer IL1. For example, in order to form the first inorganic layer IL1 including (e.g., containing) hydrogenated silicon nitride (SiNₓ:H), the first reaction gas RG1 may further include hydrogen H₂. For example, the first reaction gas RG1 may include monosilane (SiH₄), nitrogen (N₂), ammonia (NH₃), and hydrogen (H₂). By adding hydrogen (H₂) to the first reaction gas, a separate hydrogen treatment step may be omitted (e.g., not be provided) and a silicon nitride film may be hydrogenated through an integral process, thus making it possible to improve process efficiency.

Referring to FIGS. 9C and 9D, a second inorganic layer IL2 may be formed through chemical vapor deposition. In one or more embodiments of the present disclosure, the second inorganic layer IL2 may be formed through plasma enhanced chemical vapor deposition (PECVD).

The second inorganic layer IL2 may be formed on the display panel. For example, through the forming of the display panel (S100), the base substrate BS, the circuit layer DP-CL, and the display element layer DP-ED may be sequentially formed, and the second inorganic layer IL2 may be formed on the display element layer DP-ED. In some embodiments, prior to the forming of the anti-reflection layer (S200), forming the light control layer CCL (see FIG. 4A), the color filter layer CFL (see FIG. 4A), and the overcoat layer OC (see FIG. 4A) on the display panel may be performed, and as illustrated in FIG. 9C, the second inorganic layer IL2 may be deposited on the overcoat layer OC formed on the display panel.

Referring to FIGS. 9C and 9D, the forming of the second inorganic layer (S202) may be performed by providing a second reaction gas on the display panel. In some embodiments, the forming of the second inorganic layer (S202) may be performed in a deposition chamber. The second inorganic layer IL2 may be deposited in substantially the same chamber as the first inorganic layer IL1. The forming of the second inorganic layer (S202) may include forming a silicon oxide (SiOₓ) film by providing a second reaction gas RG2 on the display panel. The second reaction gas RG2 may be provided on the first inorganic layer IL1. In one or more embodiments of the present disclosure, in order to form the second inorganic layer IL2 including (e.g., containing) silicon oxide (SiOₓ), the second reaction gas RG2 may include monosilane (SiH₄) and nitrous oxide (N₂O). In this case, x corresponding to the composition ratio of silicon oxide (SiOₓ) may vary according to the ratio of each of monosilane (SiH₄) and nitrous oxide (N₂O) in the second reaction gas RG2. The second reaction gas RG2 may be injected into a chamber and ionized to be in a plasma state. Hereafter, the components of the second reaction gas RG2 in the plasma state may chemically react with each other and be deposited on the first inorganic layer IL1 to form the second inorganic layer IL2 including (e.g., containing) silicon oxide (SiOₓ) and having a set or predetermined thickness.

In some embodiments, hydrogenating the second inorganic layer may be performed after the forming of the second inorganic layer (S202). For example, hydrogen may be doped into the second inorganic layer IL2 by providing hydrogen plasma on the second inorganic layer IL2. The amount of hydrogen doped into the second inorganic layer IL2 may be adjusted by changing the flow rate and air pressure of the hydrogen (H₂) gas introduced into the chamber.

The hydrogen plasma may be doped into the second inorganic layer IL2 to increase density in the film. In the hydrogenating of the second inorganic layer IL2, by providing the hydrogen (H₂) plasma on the second inorganic layer IL2, it is possible to make silicon oxide (SiOₓ) included in the second inorganic layer IL2 react with the hydrogen plasma. For example, in the hydrogenating of the second inorganic layer IL2, by making hydrogen atoms doped into the silicon oxide thin film, it is possible to make the hydrogen atoms form new bonds with silicon atoms (Si) or oxygen atoms (O) in the silicon oxide (SiOₓ). For example, the hydrogen plasma may react with silicon oxide (SiOₓ) included in the second inorganic layer IL2 to form a Si—H bond or an O—H bond. Silicon oxide (SiOₓ) included in the second inorganic layer IL2 may be changed into hydrogenated silicon oxide (SiOₓ:H) after the hydrogenating of the second inorganic layer IL2. Accordingly, the hydrogenated second inorganic layer IL2 may have a high film density and exhibit excellent or suitable durability and reliability characteristics when applied to a display apparatus.

However, the method of hydrogenating the second inorganic layer IL2 is not limited thereto, and the hydrogenation of the second inorganic layer IL2 may be achieved by adding hydrogen (H₂) in the second reaction gas RG2 utilized to form the second inorganic layer IL2. For example, in order to form the second inorganic layer IL2 including (e.g., containing) hydrogenated silicon oxide (SiOₓ:H), the second reaction gas RG2 may further include hydrogen (H₂). For example, the second reaction gas RG2 may include monosilane (SiH₄), nitrous oxide (N₂O), and hydrogen (H₂). By adding hydrogen (H₂) to the second reaction gas RG2, a separate hydrogen treatment step may be omitted (e.g., not be provided) and a silicon oxide film may be hydrogenated through an integral process, thus making it possible to improve process efficiency.

Referring to FIG. 9E, forming a third inorganic layer IL3 and a fourth inorganic layer IL4 may be performed. The third inorganic layer IL3 and the fourth inorganic layer IL4 may be formed through chemical vapor deposition. In one or more embodiments of the present disclosure, each of the third inorganic layer IL3 and the fourth inorganic layer IL4 may be formed through plasma enhanced chemical vapor deposition (PECVD).

After the forming of the second inorganic layer (S202), forming the third inorganic layer IL3 may be performed. The third inorganic layer IL3 may be formed on the second inorganic layer IL2. The third inorganic layer IL3 may be deposited on the second inorganic layer IL2.

In some embodiments, the forming of the third inorganic layer IL3 may include providing a reaction gas for forming the third inorganic layer IL3 on the second inorganic layer IL2. In one or more embodiments of the present disclosure, the reaction gas for forming the third inorganic layer IL3 may be the same as the first reaction gas RG1 utilized to form the first inorganic layer IL1 (see FIG. 9A). The forming of the third inorganic layer IL3 may be performed in a deposition chamber. The third inorganic layer IL3 may be deposited in substantially the same chamber as the second inorganic layer IL2. The forming of the third inorganic layer IL3 may include forming a silicon nitride (SiNₓ) film by providing the first reaction gas RG1 (see FIG. 9A) on the second inorganic layer IL2. In one or more embodiments of the present disclosure, the method of forming the third inorganic layer IL3 may be the same as the method of forming the first inorganic layer IL1 described herein. In some embodiments, hydrogenating the third inorganic layer IL3 may be performed after the forming of the third inorganic layer IL3. The method of hydrogenating the third inorganic layer IL3 may be the same as the method of hydrogenating the first and second inorganic layers IL1 and IL2 described herein.

Hereafter, forming the fourth inorganic layer IL4 may be performed after the forming of the third inorganic layer IL3. The fourth inorganic layer IL4 may be formed on the third inorganic layer IL3. The fourth inorganic layer IL4 may be deposited on the third inorganic layer IL3.

In some embodiments, the forming of the fourth inorganic layer IL4 may include providing a reaction gas for forming the fourth inorganic layer IL4 on the third inorganic layer IL3. In one or more embodiments of the present disclosure, the reaction gas for forming the fourth inorganic layer IL4 may be the same as the second reaction gas RG2 utilized to form the second inorganic layer IL2 (see FIG. 9C). The forming of the fourth inorganic layer IL4 may be performed in a deposition chamber. The fourth inorganic layer IL4 may be deposited in substantially the same chamber as the third inorganic layer IL3. The forming of the fourth inorganic layer IL4 may include forming a silicon oxide (SiOₓ) film by providing the second reaction gas RG2 (see FIG. 9C) on the third inorganic layer IL3. In one or more embodiments of the present disclosure, the method of forming the fourth inorganic layer IL4 may be the same as the method of forming the second inorganic layer IL2 described herein. In some embodiments, hydrogenating the fourth inorganic layer IL4 may be performed after the forming of the fourth inorganic layer IL4. The method of hydrogenating the fourth inorganic layer IL4 may be the same as the method of hydrogenating the first and second inorganic layers IL1 and IL2 described herein.

In some embodiments, in the method of manufacturing the display apparatus described with reference to FIGS. 9A to 9E, it is illustrated by example that the first inorganic layer IL1 is first formed on the overcoat layer OC and then the second inorganic layer IL2 is formed on the first inorganic layer IL1, but the embodiment of the present disclosure is not limited thereto. For example, unlike what is illustrated, the second inorganic layer IL2 may be first formed on the overcoat layer OC and then the first inorganic layer IL1 may be formed on the second inorganic layer IL2.

In some embodiments, in the forming of the anti-reflection layer (S200), the forming of the first inorganic layer (S201) and the forming of the second inorganic layer (S202) may be sequentially and repeatedly performed. For example, when the forming of the first inorganic layer (S201) and the forming of the second inorganic layer (S202) are referred to as a first process and the forming of the third inorganic layer and the forming of the fourth inorganic layer are referred to as a second process, the second process may be performed after the first process is repeatedly performed n or more times. Here, n may be an integer of 2 to 10. The anti-reflection layer manufactured through this process may have the structure of FIG. 5B or FIG. 5C.

In some embodiments, the method of manufacturing the display apparatus according to one or more embodiments of the present disclosure may further include forming a low refraction layer OL (see FIG. 5D) on the fourth inorganic layer IL4 after the forming of the fourth inorganic layer IL4.

In some embodiments, in the method of manufacturing the display apparatus according to one or more embodiments of the present disclosure, forming a fifth inorganic layer IL5 (see FIG. 5E) may be further performed before the forming of the first inorganic layer IL1. The method of forming the fifth inorganic layer IL5 may be the same as the method of forming the second inorganic layer IL2 described herein. In this case, the first to fifth inorganic layers IL1, IL2, IL3, IL4, and IL5 may be formed in a same chamber.

According to one or more embodiments of the present disclosure, the reflectance of external light incident on a display apparatus may be reduced by providing an anti-reflection layer on one surface of the display apparatus on which external light is incident.

According to one or more embodiments of the present disclosure, as the display apparatus includes an anti-reflection layer including a first inorganic layer and a second inorganic layer having different materials and refractive indices, the display apparatus may exhibit low reflectance and improved resistance to a high-temperature and high-humidity environment, thus making it possible to improve the visibility and reliability of the display apparatus.

Although the described has been described with reference to preferred embodiments of the present disclosure, those skilled in the art or those of ordinary skill in the art will understand that one or more suitable modifications and changes can be made to the present disclosure within the scope that does not depart from the spirit and technical field of the present disclosure described in the claims to be described later. Accordingly, the technical scope of the present disclosure should not be limited to the content (e.g., amount) described in the detailed description of the specification, but should be determined by the claims described hereinafter, and equivalents thereof.

What is claimed is:

1. A display apparatus comprising:
a display panel;
a light control layer on the display panel; and
an anti-reflection layer on the light control layer,
wherein the anti-reflection layer comprises a plurality of inorganic layers,
wherein the plurality of inorganic layers comprises:
a first inorganic layer comprising silicon nitride (SiNₓ, x is an integer of 1 or more);
a second inorganic layer comprising silicon oxide (SiOₓ, x is an integer of or more);
a third inorganic layer comprising silicon nitride; and
a fourth inorganic layer comprising silicon oxide, and
wherein:
each of the first inorganic layer and the third inorganic layer has a first refractive index; and
each of the second inorganic layer and the fourth inorganic layer has a second refractive index less than the first refractive index.

2. The display apparatus of claim 1, wherein:
the first refractive index is about 1.80 to about 2.00 at a wavelength of about 550 nanometer (nm); and
the second refractive index is about 1.40 to about 1.50 at a wavelength of about 550 nm.

3. The display apparatus of claim 1, wherein a thickness of each of the first inorganic layer and the second inorganic layer is about 10 nm to about 30 nm.

4. The display apparatus of claim 1, wherein:
a thickness of the third inorganic layer is about 100 nm to about 150 nm; and
a thickness of the fourth inorganic layer is about 10 nm to about 30 nm.

5. The display apparatus of claim 1, wherein the first inorganic layer, the second inorganic layer, the third inorganic layer, and the fourth inorganic layer are sequentially stacked.

6. The display apparatus of claim 1, wherein:
the plurality of inorganic layers comprises a plurality of first inorganic layers and a plurality of second inorganic layers; and
the plurality of first inorganic layers and the plurality of second inorganic layers are alternately stacked on each other.

7. The display apparatus of claim 6, wherein:
the plurality of first inorganic layers comprises a (1-1)-th inorganic layer and a (1-2)-th inorganic layer; and
the plurality of second inorganic layers comprises a (2-1)-th inorganic layer and a (2-2)-th inorganic layer,
wherein the (1-1)-th inorganic layer, the (2-1)-th inorganic layer, the (1-2)-th inorganic layer, and the (2-2)-th inorganic layer are sequentially stacked.

8. The display apparatus of claim 1, further comprising an overcoat layer between the light control layer and the anti-reflection layer,
wherein the anti-reflection layer is on an upper surface of the overcoat layer.

9. The display apparatus of claim 8, wherein:
the first inorganic layer is directly on the overcoat layer;
the second inorganic layer is directly on the first inorganic layer; and
the third inorganic layer is directly on the second inorganic layer.

10. The display apparatus of claim 1, wherein at least one of the first inorganic layer, the second inorganic layer, the third inorganic layer, or the fourth inorganic layer is hydrogenated.

11. The display apparatus of claim 9, wherein:
the first inorganic layer comprises hydrogenated silicon nitride (SiNₓ:H); and
the second inorganic layer comprises hydrogenated silicon oxide (SiOₓ:H).

12. The display apparatus of claim 1, wherein:
the plurality of inorganic layers further comprises a fifth inorganic layer comprising silicon oxide; and
the fifth inorganic layer, the first inorganic layer, the second inorganic layer, the third inorganic layer, and the fourth inorganic layer are sequentially stacked.

13. The display apparatus of claim 1, wherein:
the anti-reflection layer further comprises an organic layer on the plurality of inorganic layers; and
an upper surface of the organic layer comprises an outermost surface of the anti-reflection layer.

14. The display apparatus of claim 13, wherein:
a refractive index of the organic layer is about 1.25 to about 1.30; and
a thickness of the organic layer is about 60 nm to about 110 nm.

15. The display apparatus of claim 1, further comprising a color filter layer between the light control layer and the anti-reflection layer.

16. The display apparatus of claim 1, wherein:
the display panel comprises a plurality of light-emitting elements configured to generate a first light; and
the light control layer comprises:
a first light control unit configured to transmit the first light;
a second light control unit configured to convert the first light into a second light having a wavelength different from that of the first light; and
a third light control unit configured to convert the first light into a third light having a wavelength different from each of those of the first light and the second light.

17. The display apparatus of claim 1, wherein a reflectance of an upper surface of the anti-reflection layer is about 2% or less.

18. A display apparatus comprising:
a display panel;
a light control layer directly on the display panel; and
an anti-reflection layer on the light control layer,
wherein the anti-reflection layer comprises a plurality of inorganic layers,
wherein the plurality of inorganic layers comprises:
a plurality of first inorganic layers having a first refractive index and comprising silicon nitride (SiNₓ, x is an integer of 1 or more); and
a plurality of second inorganic layers having a second refractive index less than the first refractive index and comprising silicon oxide (SiOₓ, x is an integer of 1 or more), and
wherein the plurality of first inorganic layers and the plurality of second inorganic layers are alternately stacked by at least two layers.

19. A method for manufacturing a display apparatus, the method comprising:
forming a display panel; and
forming an anti-reflection layer on the display panel,
wherein the forming of the anti-reflection layer comprises:
forming a plurality of first inorganic layers having a first refractive index by providing a first reaction gas comprising SiH₄, N₂, and NH₃ on the display panel; and
forming a plurality of second inorganic layers having a second refractive index less than the first refractive index by providing a second reaction gas comprising SiH₄, and N₂O on the display panel, and
wherein each of the plurality of first inorganic layers and the plurality of second inorganic layers are alternately stacked by at least two layers.

20. The method of claim 19, further comprising at least one of hydrogenating at least one selected from among the plurality of first inorganic layers by providing hydrogen (H₂) gas on the at least one selected from among the plurality of first inorganic layers or hydrogenating at least one selected from among the plurality of second inorganic layers by providing hydrogen (H₂) gas on the at least one selected from among the plurality of second inorganic layers.
